(19) United States
(12) Patent Application Publication
(10) Pub. No.: US 2026/0231375 A1
(43) Pub. Date: Aug. 6, 2026

(54) LIQUID COOLING OF ELECTRONIC COMPONENTS

(71) Applicant: Cisco Technology, Inc., San Jose, CA (US)

(72) Inventors: Joseph F. Jacques, Austin, TX (US); Joel Richard Goergen, Soulsbyville, CA (US); Mark Nowell, Kanata (CA); Edward Warnicke, Austin, TX (US); Christopher David Liljenstolpe, San Francisco, CA (US)

(21) Appl. No.: 19/217,637

(22) Filed: May 23, 2025

Related U.S. Application Data
(60) Provisional application No. 63/752,475, filed on Jan. 31, 2025.

(51) Int. Cl. H05K 7/20

(52) U.S. Cl. CPC H05K 7/20772; H05K 7/20272; H05K 7/20281; H05K 7/20418

(57) ABSTRACT

In one embodiment, a cold tray assembly mounted to a PCB includes a manifold tank, a plurality of baffle walls within the manifold tank, the plurality of baffle walls defining one or more flow paths for a liquid coolant in the manifold tank, and one or more slots within a surface of the manifold tank, the one or more slots corresponding to at least one cold plate thermally coupled to one or more components of the PCB, where the one or more slots are configured to transfer the liquid coolant between the manifold tank and the at least one cold plate to dissipate heat from the one or more components to the liquid coolant.

### CROSS-REFERENCE TO RELATED APPLICATIONS

This application claims the benefit of priority to U.S. Provisional Application No. 63/752,475, filed Jan. 31, 2025, the disclosure of which is incorporated by reference herein in its entirety.

### TECHNICAL FIELD

The present disclosure relates to thermal management systems. More particularly, the present disclosure relates to cold tray assemblies for liquid cooling of electronic components.

### BACKGROUND

As modern computing workloads rely on high-performance electronic components such as, but not limited to, Graphics Processing Units (GPUs) and Central Processing Units (CPUs) packed into compact server enclosures, the thermal power densities of systems have increased. Traditional air-based cooling methods are becoming less effective due to limited airflow paths, higher ambient temperatures, and rising heat flux densities.

The limitations of conventional cooling methods under these conditions can result in thermal throttling, reduced reliability, or system failures. To address the needs of high-performance electronic components, liquid cooling solutions may be employed. However, traditional liquid cooling solutions may face challenges such as high pressure drops, uneven coolant distribution, mechanical constraints, integration complexity, or the like. As a result, the traditional cooling solutions may fall short of managing extreme heat loads, limiting their ability to meet the increasing thermal demands of next-generation electronic systems.

### BRIEF DESCRIPTION OF THE DRAWINGS

FIG. 1 is a diagram that illustrates a cross-sectional view of a cold tray assembly mounted to a printed circuit board (PCB) in accordance with various embodiments of the disclosure;

FIG. 2 is a diagram that illustrates an exploded view of a cold tray assembly in accordance with various embodiments of the disclosure;

FIG. 3 is a diagram that illustrates a perspective view of a cold tray assembly mounted on a PCB in accordance with one or more embodiments of the disclosure;

FIG. 4A is a diagram that illustrates a perspective view of an internal flow arrangement within a cold tray assembly in accordance with various embodiments of the disclosure;

FIG. 4B is a diagram that illustrates a coolant flow path for a cold tray assembly in accordance with various embodiments of the disclosure;

FIG. 5 is a diagram that illustrates an exploded view of an upper wall of a manifold tank of a cold tray assembly in accordance with various embodiments of the disclosure;

FIG. 6 is a diagram that illustrates configurations of a hollow pedestal of a cold tray assembly in accordance with various embodiments of the disclosure;

FIG. 7A is a diagram that illustrates a cross-sectional view of a dual cold tray device in accordance with various embodiments of the disclosure;

FIG. 7B is a diagram that illustrates an exploded view of a dual cold tray device in accordance with various embodiments of the disclosure;

FIG. 8 is a diagram that illustrates an exploded view of a first cold tray assembly and a PCB of a dual cold tray device in accordance with various embodiments of the disclosure;

FIG. 9 is a diagram that illustrates an exploded view of a second cold tray assembly and a PCB of a dual cold tray device in accordance with various embodiments of the disclosure;

FIG. 10A is a diagram that illustrates a perspective view of a coolant flow path of a first cold tray assembly of a dual cold tray device in accordance with various embodiments of the disclosure;

FIG. 10B is a diagram that illustrates a perspective view of a coolant flow path of a second cold tray assembly of a dual cold tray device in accordance with various embodiments of the disclosure;

FIG. 11A is a diagram that illustrates a first top-down view of a fin array of a dual cold tray device in accordance with various embodiments of the disclosure;

FIG. 11B is a diagram that illustrates a second top-down view of a fin array of a dual cold tray device in accordance with various embodiments of the disclosure;

FIG. 11C is a diagram that illustrates a third top-down view of a fin array of a dual cold tray device in accordance with various embodiments of the disclosure;

FIG. 12A is a diagram that illustrates a perspective view of a cold plate for a component mounted on a PCB in accordance with various embodiments of the disclosure;

FIG. 12B is a diagram that illustrates an exploded view of a cold tray device integrating one or more cold plates for one or more high-power components mounted on a PCB in accordance with various embodiments of the disclosure;

FIG. 13 is a diagram that illustrates an exploded view of a cold tray device comprising a cold tray assembly and a PCB in accordance with various embodiments of the disclosure;

FIG. 14 is a diagram that illustrates a perspective view of a cold tray assembly in accordance with various embodiments of the disclosure; and

FIG. 15 is a diagram that illustrates a top-down schematic view of a coolant flow path of a cold tray assembly in accordance with various embodiments of the disclosure.

Corresponding reference characters indicate corresponding components throughout the several figures of the drawings. Elements in the several figures are illustrated for simplicity and clarity and have not necessarily been draw n to scale. For example, the dimensions of some of the elements in the figures might be emphasized relative to other elements for facilitating understanding of the various presently disclosed embodiments. In addition, common, but well-understood, elements that are useful or necessary in a commercially feasible embodiment are often not depicted in order to facilitate a less obstructed view of these various embodiments of the present disclosure.

### DESCRIPTION OF EXAMPLE EMBODIMENTS

### Overview

In many embodiments, a cold tray assembly mounted to a printed circuit board (PCB) includes a manifold tank, one or more pedestals that extend outward from the manifold tank, the one or more pedestals configured to thermally couple with one or more components of the PCB, and a plurality of baffle walls within the manifold tank, the plurality of baffle walls defining one or more flow paths for a liquid coolant in the manifold tank, where the one or more pedestals are further configured to transfer heat from the one or more components of the PCB to the liquid coolant.

In numerous embodiments, a cold tray assembly mounted to a PCB includes a manifold tank, a plurality of baffle walls within the manifold tank, the plurality of baffle walls defining one or more flow paths for a liquid coolant in the manifold tank, and one or more slots within a surface of the manifold tank, the one or more slots corresponding to at least one cold plate thermally coupled to one or more components of the PCB, where the one or more slots are configured to transfer the liquid coolant between the manifold tank and the at least one cold plate to dissipate heat from the one or more components to the liquid coolant.

### Example Embodiments

In response to the issues described above, devices and methods are discussed herein that improve liquid cooling of electronic components. A cold tray assembly (e.g., lower cold tray assembly) may be positioned beneath a printed circuit board (PCB) for cooling high-power and low-power electronic components mounted on a bottom side of the PCB. In many embodiments, the lower cold tray assembly may include a manifold tank with internal baffle walls and pedestals (solid or hollow), to manage heat extraction from the components. In a variety of embodiments, the pedestals may be thermally coupled to the heat-generating components. In a number of embodiments, the pedestals may be configured to transfer heat from the heat-generating components to a circulating liquid coolant. Depending on the thermal load, hollow pedestals with internal fins or channels may be used to allow direct coolant flow, enhancing convective cooling.

The lower cold tray assembly may provide direct thermal conduction from densely packed bottom-side components, and mechanical support and thermal coupling via the pedestals. In more embodiments, the lower cold tray assembly may be scalable and suitable for 1 Rack Unit (RU) server systems with reduced reliance on external heat sinks or airflow mechanisms.

In further embodiments, a cold tray assembly (e.g., upper cold tray assembly) may be positioned above the PCB to cool top-side components of the PCB. The upper cold tray assembly may include a manifold tank, internal baffle walls, pedestals, and one or more slots. In additional embodiments, the PCB may include dedicated cold plates thermally coupled to high-power components such that the one or more slots of the upper cold tray assembly may correspond to or mate with the dedicated cold plates of the PCB. In still more embodiments, the upper cold tray assembly may provide integrated cooling for components without external fins or airflow, and seamless lid-level integration reducing part count and system height. In still further embodiments, the upper cold tray assembly may maintain a uniform temperature distribution across the surface of the upper cold tray assembly.

In still additional embodiments, a dual cold tray device may include the PCB, an upper (or a first) cold tray assembly, and a lower (or a second) cold tray assembly. The PCB may be sandwiched between the first and the second cold tray assemblies, enabling two-sided cooling. In some more embodiments, the dual configuration of the cold tray assemblies may be implemented using independent or interconnected coolant loops, depending on thermal and hydraulic balancing requirements. Coolant may flow in series, parallel, or through support columns acting as fluidic interconnects between the first cold tray assembly and the second cold tray assembly. Therefore, the dual cold tray device may provide simultaneous heat extraction from both sides of the PCB and enhanced cooling capacity (for example, exceeding 4600 Watts (W)) of component load, among other like advantages and use cases.

Before some particular embodiments are provided in greater detail, it should be understood that the particular embodiments provided herein do not limit the scope of the concepts provided herein. It should also be understood that a particular embodiment provided herein can have features that can be readily separated from the particular embodiment and optionally combined with or substituted for features of any of a number of other embodiments provided herein.

Regarding terms used herein, it should also be understood the terms are for the purpose of describing some particular embodiments, and the terms do not limit the scope of the concepts provided herein. Ordinal numbers (e.g., first, second, third, etc.) are generally used to distinguish or identify different features or steps in a group of features or steps, and do not supply a serial or numerical limitation. For example, “first,” “second,” and “third” features or steps need not necessarily appear in that order, and the particular embodiments including such features or steps need not necessarily be limited to the three features or steps. Labels such as “left,” “right,” “front,” “back,” “top,” “bottom,” “forward,” “reverse,” “clockwise,” “counter clockwise,” “up,” “down,” or other similar terms such as “upper,” “lower,” “aft,” “fore,” “vertical,” “horizontal,” “proximal,” “distal,” and the like are used for convenience and are not intended to imply, for example, any particular fixed location, orientation, or direction. Instead, such labels are used to reflect, for example, relative location, orientation, or directions. Singular forms of “a,” “an,” and “the” include plural references unless the context clearly dictates otherwise. Finally, unless defined otherwise, all technical and scientific terms used herein have the same meaning as commonly understood by those of ordinary skill in the art.

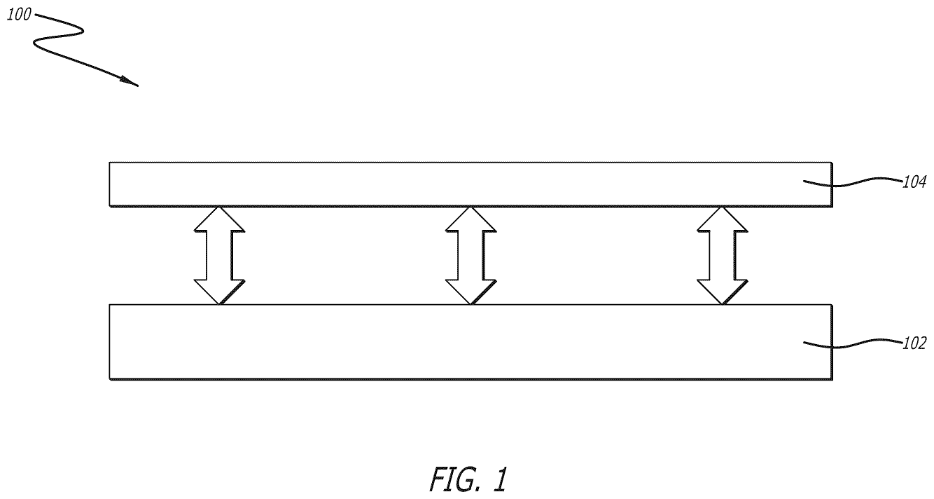

Referring to FIG. 1, a diagram that illustrates a cross-sectional view 100 of a cold tray assembly 102 mounted to a printed circuit board (PCB) 104 in accordance with various embodiments of the disclosure is shown. In many embodiments, the cold tray assembly 102 may be configured for thermal management for one or more heat-generating components (interchangeably referred to as “one or more components” or “components” herein) mounted on the PCB 104. In a number of embodiments, the one or more components mounted on the PCB 104 may include, but are not limited to, Application-Specific Integrated Circuits (ASICs), Graphics Processing Units (GPUs), Central Processing Units (CPUs), Network Processing Units (NPUs), optical modules, power delivery modules, Field-Programmable Gate Arrays (FPGAs), memory devices, or the like.

During operation, the one or more components mounted on the PCB 104 can dissipate heat due to computational density, switching speeds, and continuous operation under high workloads. The cold tray assembly 102 may improve signal integrity, processing speed, timing, or the like.

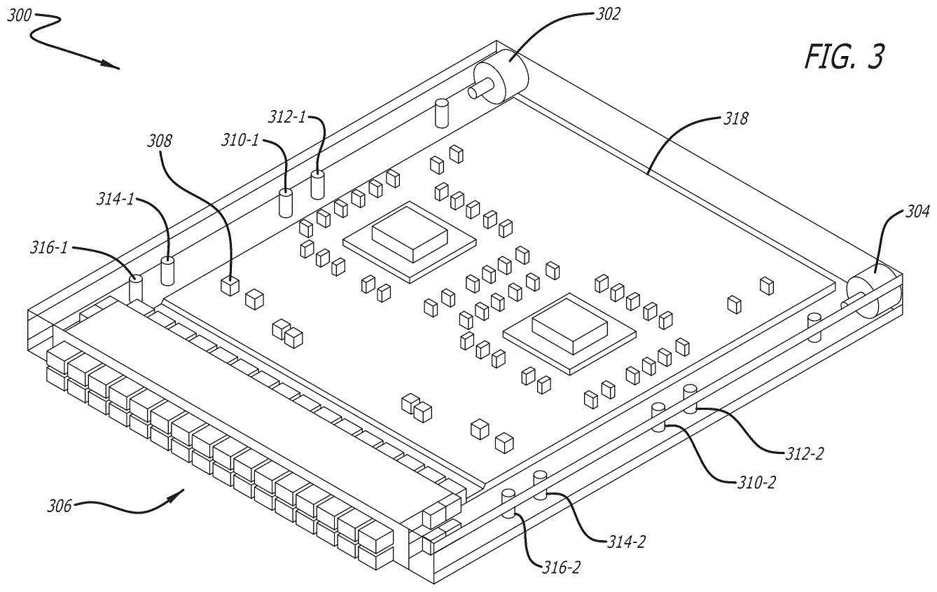

In a variety of embodiments, the one or more components may be thermally coupled to the cold tray assembly 102 to transfer heat from the one or more components to the cold tray assembly 102, for example, through direct thermal conduction. In more embodiments, a liquid coolant may enter the cold tray assembly 102 through one or more inlets (shown as 302 in FIG. 3), flow through the cold tray assembly 102, and exit through one or more outlets (shown as 304 in FIG. 3). The liquid coolant may include, but is not limited to, deionized water, water-glycol mixtures, dielectric fluids, or the like.

In additional embodiments, as the one or more components operate, heat may be transferred from the one or more components into the cold tray assembly 102. The liquid coolant flowing through the cold tray assembly 102 may absorb the heat transferred from the one or more components, carry away the absorbed heat, and exit the cold tray assembly 102 via the one or more outlets. In further embodiments, the liquid coolant may be directed to a remote heat exchanger or radiator from the one or more outlets. This may enable localized heat extraction, avoiding reliance on ambient airflow.

In still more embodiments, the cold tray assembly 102 may be integrated into the base of a chassis that houses the PCB 104. In an example, the cold tray assembly 102 may be integrated in 1 RU server systems. In more examples, the cold tray assembly 102 may be utilized in optical line cards or network interface cards (NICs). In more examples, the cold tray assembly 102 may be integrated in telecom baseband processing units. In more examples, the cold tray assembly 102 may be integrated in edge compute or industrial controllers, improving thermal performance in sealed enclosures without relying on external airflow. In more examples, the cold tray assembly 102 may be integrated in similar systems comprising heat-generating components.

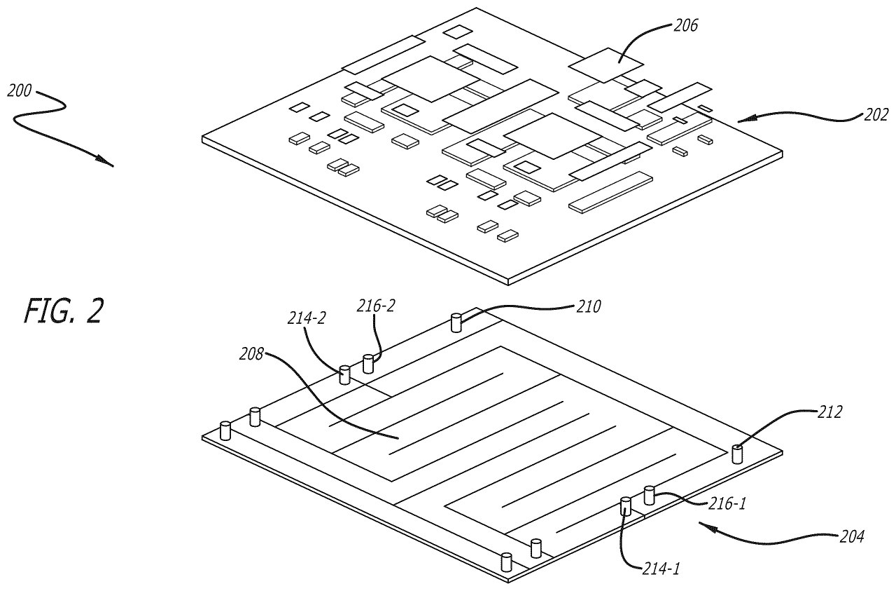

In still further embodiments, the cold tray assembly 102 may operate as a direct liquid cooling (DLC) device to extract heat from the one or more components mounted, for example, on the bottom side of the PCB 104. In still additional embodiments, the cold tray assembly 102 may extract the heat from the one or more components via thermally conductive pedestals or cold plate interfaces, which is explained in further detail with reference to FIGS. 2-15 . Structurally, the cold tray assembly 102 may replace or reinforce the base of the chassis, providing mechanical rigidity and supporting the overall assembly during operation, transportation, and mounting in rack systems. In this way, the overall assembly may maximize the volumetric efficiency, eliminating the need for bulky components such as heat sinks, fans, airflow ducting, or the like. Further, reducing the number of discrete components may simplify the mechanical design, improve manufacturability, and enable tighter thermal coupling between high-power components and the cooling infrastructure, thereby enabling high-efficiency and scalable cooling assemblies suitable for next-generation computing platforms, optical line cards, or the like.

Though FIG. 1 illustrates the cold tray assembly 102 to be arranged in a specific configuration, the scope of the disclosure is not limited to it. In additional implementations, the cold tray assembly 102 can be arranged in any other suitable configuration than the one shown in FIG. 1. For example, the cold tray assembly 102 can be arranged on any side of the PCB 104 (for example, top side) depending on system-level thermal requirements, available space, and airflow characteristics.

Although a specific embodiment for a cold tray assembly 102 suitable for carrying out the various steps, processes, methods, and operations described herein is discussed with respect to FIG. 1, any of a variety of systems and/or processes may be utilized in accordance with embodiments of the disclosure. For example, the cold tray assembly 102 may distribute a liquid coolant to one or more discrete cold plates mounted elsewhere on the PCB 104. The elements depicted in FIG. 1 may also be interchangeable with other elements of FIGS. 2-15 as required to realize a particularly desired embodiment.

Referring to FIG. 2, a diagram that illustrates an exploded view of a cold tray assembly 200 in accordance with various embodiments of the disclosure is shown. In one or more embodiments, the cold tray assembly 200 of FIG. 2 may be similar to the cold tray assembly 102 of FIG. 1. In many embodiments, the cold tray assembly 200 may be positioned below a PCB (for example, the PCB 104 of FIG. 1) to thermally manage one or more heat-generating components mounted thereon. As discussed herein, the PCB may include one or more components such as ASICs, CPUs, memory devices, optical modules, or the like.

In a number of embodiments, the cold tray assembly 200 may include a manifold tank formed between an upper surface (or wall) 202 and a lower surface (or wall) 204, joined by a plurality of sidewalls. The manifold tank may be a sealed enclosure through which a liquid coolant (or a coolant) is circulated to extract heat from the one or more components mounted on the PCB. In a variety of embodiments, the manifold tank may be fabricated from thermally conductive materials such as, but not limited to, aluminum or copper, or from composite materials selected for strength, corrosion resistance, and compatibility with different coolant types. In more implementations, the cold tray assembly 200 may be integrated into a base of a chassis housing the PCB. For example, the upper wall 202 of the manifold tank may form part of the chassis base or lid and include openings or slots to interface with the one or more components or external cold plates mounted to high-power components on the PCB. In additional embodiments, the manifold tank may act as a thermal sink and a coolant distribution chamber, absorbing heat from attached or embedded thermally conductive elements and efficiently routing the coolant to transfer heat away from the one or more components of the PCB.

In further embodiments, the cold tray assembly 200 may include one or more pedestals 206 (interchangeably referred to as “pedestals 206” or “pedestal 206”). The pedestals 206 may refer to one or more thermally conductive structures that extend outward from the manifold tank (for example, from the upper wall 202 of the manifold tank). In still more embodiments, the one or more pedestals 206 may be configured to thermally couple with the one or more components mounted on the PCB and to transfer heat from the one or more components into the liquid coolant circulating within the manifold tank. The one or more pedestals 206 may form a thermal interface between the one or more components and the liquid coolant, enabling efficient heat transfer by conduction. In still additional embodiments, each pedestal 206 may be dimensioned and positioned to align with a specific component (e.g., ASIC, CPU, memory device, optical module, or the like) on the PCB (for example, the bottom side of the PCB 104). The pedestal 206 may include a thermally conductive core and a compressible thermal interface material (TIM) in the form of a gap pad on an external surface of the pedestal 206 to accommodate mechanical tolerances, improve surface contact, and minimize thermal resistance. In still further embodiments, the pedestal 206 may include a spring-loaded mechanism or structure to maintain consistent contact pressure under thermal expansion or vibration conditions. In one or more embodiments, the pedestals 206 may be attached to the manifold tank by soldering, welding, brazing, or the like.

The one or more pedestals 206 may be formed in a variety of geometries depending on the application. In still more embodiments, a pedestal 206 may correspond to a solid pedestal. In such configurations, the pedestal 206 may be composed of a block of thermally conductive material, such as but not limited to, copper or aluminum, which directly conducts heat into the coolant within the manifold tank. In still further embodiments, a pedestal 206 may correspond to a hollow pedestal. In such configurations, the pedestal 206 may include a set of internal fins or channels that enable the coolant to flow directly around or through the pedestal 206, further enhancing convective heat transfer and cooling efficiency. In still additional embodiments, the pedestals 206 may improve mechanical stability, acting as support posts that align and reinforce the PCB relative to the cold tray assembly 200. This may be useful in high-density electronic assemblies where board deflection or misalignment is to be avoided.

In some more embodiments, the cold tray assembly 200 may include a plurality of baffle walls 208 that extend within the manifold tank. The plurality of baffle walls 208 may define one or more flow paths or channels for the liquid coolant in the manifold tank. The plurality of baffle walls 208 may guide the liquid coolant to circulate through the manifold tank. In yet more embodiments, the manifold tank may include an inlet 210 to receive the coolant into the manifold tank. In still yet more embodiments, the manifold tank may include an outlet 212 to eject the coolant from the manifold tank. During operation, the coolant may enter the manifold tank through the inlet 210, flow through the one or more flow paths defined by the plurality of baffle walls 208 where heat may be transferred from the pedestals 206, and then eject from the manifold tank through the outlet 212.

In many further embodiments, the one or more flow paths may include various configurations including, but not limited to, a serpentine flow path, a parallel flow path, a radial flow path, a spiral flow path, or other application-specific configurations. In the embodiment shown in FIG. 2, the coolant may enter the manifold tank and may be directed through a continuous back-and-forth flow path, for example, serpentine flow path, defined by the plurality of baffle walls 208. In one or more embodiments, in the parallel flow path, the coolant may split into multiple parallel channels that run side-by-side through the manifold tank. In the radial flow path, the coolant may enter the manifold tank from the inlet 210 and radiate outward through multiple spoke-like passages. In more implementations, the one or more flow paths can be arranged in any other suitable configuration than the one shown in FIG. 2, depending on system-level thermal requirements, available space, and airflow characteristics.

In many additional embodiments, the manifold tank may include a set of first ports 214-1, 214-2 configured to connect to external cold plates mounted on the PCB. The set of first ports 214-1, 214-2 may eject the coolant from the manifold tank to circulate through one or more external cold plates that may be thermally coupled to high-power components mounted on the PCB. This may extend the cooling capability of the cold tray assembly 200 beyond its thermal footprint. In still yet further embodiments, the manifold tank may include a set of second ports 216-1, 216-2, corresponding to the set of first ports 214-1, 214-2, to receive the coolant from the one or more external cold plates back into the manifold tank. In this way, the cold tray assembly 200 may transfer heat from the high-power components to the one or more external cold plates, and back into the manifold tank via the set of first ports 214-1, 214-2 and the set of second ports 216-1, 216-2. In one or more embodiments, the set of first ports 214-1, 214-2 and the set of second ports 216-1, 216-2 may correspond to, but are not limited to, female universal quick disconnect sockets.

Although a specific embodiment for a cold tray assembly 200 suitable for carrying out the various steps, processes, methods, and operations described herein is discussed with respect to FIG. 2, any of a variety of systems and/or processes may be utilized in accordance with embodiments of the disclosure. For example, the lower wall 204 and the side walls of the manifold tank may be fabricated from thermally non-conductive, lighter materials. The elements depicted in FIG. 2 may also be interchangeable with other elements of FIG. 1 and FIGS. 3-15 as required to realize a particularly desired embodiment.

Referring to FIG. 3, a diagram that illustrates a perspective view of a cold tray assembly 300 mounted on a PCB 306 in accordance with one or more embodiments of the disclosure is shown. In one or more embodiments, the cold tray assembly 300 of FIG. 3 may be similar to the cold tray assembly 200 of FIG. 2. In many embodiments, the cold tray assembly 300 may be mounted on a bottom side of the PCB 306 and integrated into a chassis structure defined in part by sidewalls and external covers. In a number of embodiments, the PCB 306 may include one or more heat-generating components 308 such as ASICs, NPUs, memory devices, optical modules, or the like, requiring efficient thermal management. In the embodiment shown in FIG. 3, the cold tray assembly 300 may include a manifold tank 318 enclosed by a lower wall and an upper wall (for example, the lower wall 204 and the upper wall 202 of FIG. 2).

In a variety of embodiments, the manifold tank 318 of the cold tray assembly 300 may include an inlet 302 and an outlet 304 that interface with a centralized liquid cooling loop. In one or more embodiments, the inlet 302 and the outlet 304 may correspond to, but are not limited to, blind mate quick disconnect sockets. A coolant may enter the manifold tank 318 through the inlet 302 and exit through the outlet 304 after circulating through internal flow paths defined by a plurality of baffle walls (for example, the plurality of baffle walls 208 of FIG. 2). The flow paths within the manifold tank 318 may be arranged in a serpentine or parallel or other like flow configurations for effective heat absorption. In more embodiments, the inlet 302 and the outlet 304 may include quick-connect fittings or barbed elbows designed for integration with flexible tubing.

In further embodiments, the cold tray assembly 300 may include one or more pedestals (for example, the one or more pedestals 206 of FIG. 2) that extend upward from the manifold tank 318 and may be aligned with the one or more components 308 mounted on the PCB 306. The pedestals may be configured to transfer heat from the components 308 into a liquid coolant circulating within the manifold tank 318.

In additional embodiments, the cold tray assembly 300 may include a first pair of coolant supply ports 310-1 and 310-2 that interface with one or more cold plates mounted to the PCB 306 and configured to thermally couple with the one or more components 308 (for example, NPUs) on the PCB 306. The first pair of coolant supply ports 310-1, 310-2 may be configured to supply the coolant to the one or more cold plates for localized cooling of the one or more components 308. A corresponding first pair of coolant return ports 312-1 and 312-2 may be configured to receive the warmed coolant from the one or more cold plates and direct it back into the manifold tank 318. In still more embodiments, the cold tray assembly 300 may include a second pair of coolant supply ports 314-1 and 314-2 that interface with one or more components 308 mounted to the PCB 306 (for example, optical modules). A corresponding second pair of coolant return ports 316-1 and 316-2 may receive the warmed coolant and direct it back into the manifold tank 318. During operation, the coolant may enter the manifold tank 318 through the inlet 302, flow through the flow paths defined by the plurality of baffle walls extracting heat from the one or more pedestals, flow to the first pair of coolant supply ports 310-1, 310-2 and the second pair of coolant supply ports 314-1, 314-2, and exit the manifold tank 318 through the outlet 304. This closed-loop flow may support thermal control of board-mounted modules with minimal tubing complexity. In one or more embodiments, the first pair of coolant supply ports 310-1, 310-2, the second pair of coolant supply ports 314-1, 314-2, the first pair of coolant return ports 312-1, 312-2, and the second pair of coolant return ports 316-1, 316-2 may correspond to, but not limited to, female universal quick disconnect sockets. In additional embodiments, the first pair of coolant supply ports 310-1, 310-2 of FIG. 3 may correspond to the set of first ports 214-1, 214-2 of FIG. 2, and the first pair of coolant return ports 312-1, 312-2 of FIG. 3 may correspond to the set of second ports 216-1, 216-2 of FIG. 2.

In still further embodiments, the cold tray assembly 300 may be structurally integrated into a base portion of a chassis to minimize system height and maximize mechanical rigidity. This may be beneficial in dense form factors such as 1 RU server systems. In still additional embodiments, the cold tray assembly 300 may enable co-location of high-power and low-power modules, simplify tubing layouts, and ensure thermal uniformity across the PCB 306.

Although a specific embodiment for a cold tray assembly 300 suitable for carrying out the various steps, processes, methods, and operations described herein is discussed with respect to FIG. 3, any of a variety of systems and/or processes may be utilized in accordance with embodiments of the disclosure. For example, positioning of tubing and pedestals of the cold tray assembly 300 may be configurable and scalable based on the layout of the PCB 306. The pedestals may be arranged to align with the placement of the one or more components 308 on the PCB 306. Similarly, the location of the tubing ports may be adjusted to accommodate space constraints, optimize coolant routing, and balance flow distribution across high-power components 308 of the PCB 306. This flexible architecture may allow the cold tray assembly 300 to be adapted for a variety of PCB configurations and use cases, including but not limited to, server blades, switch line cards, or pluggable computing modules, and ensure efficient thermal coupling and minimal pressure drop in the cooling loop. The elements depicted in FIG. 3 may also be interchangeable with other elements of FIGS. 1-2 and FIGS. 4-15 as required to realize a particularly desired embodiment.

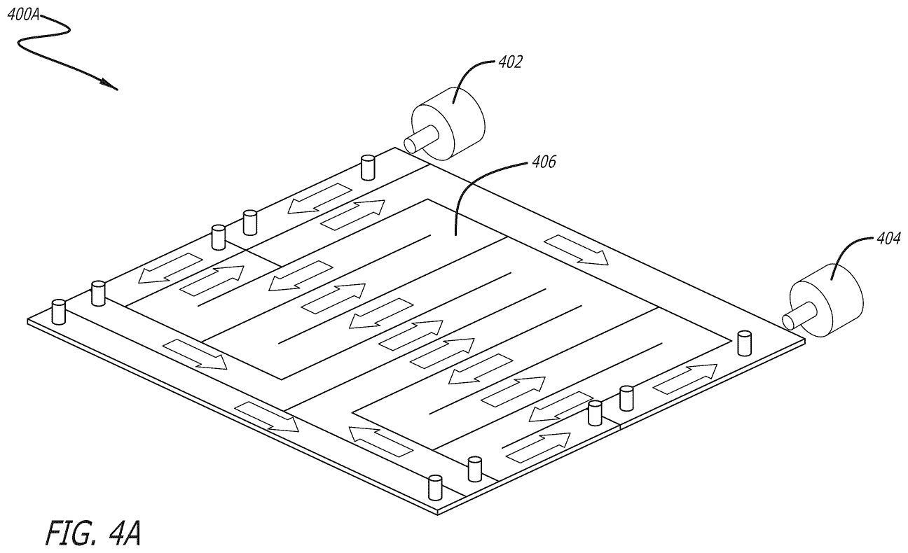

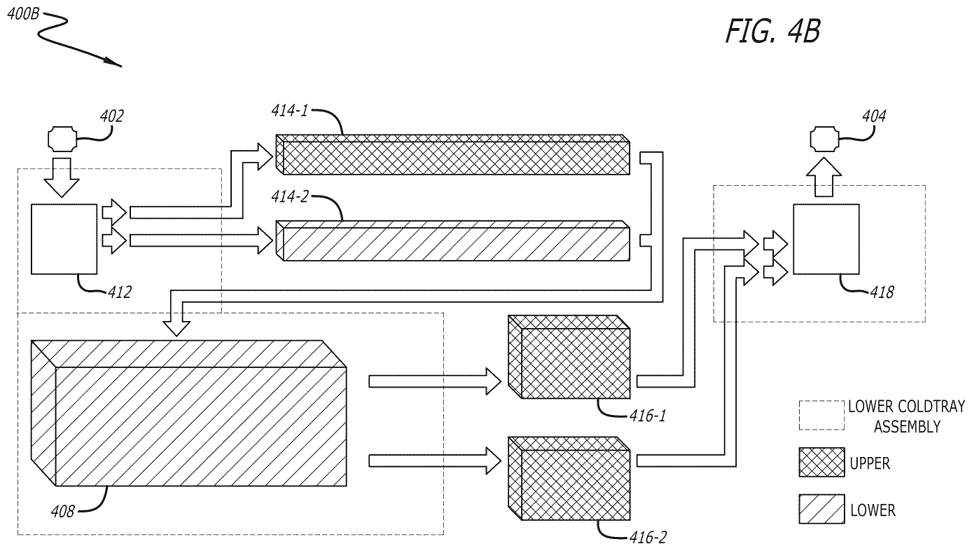

Referring to FIG. 4A, a diagram that illustrates a perspective view of an internal flow arrangement within a cold tray assembly 400A in accordance with various embodiments of the disclosure is shown. In one or more embodiments, the cold tray assembly 400A of FIG. 4A may be similar to the cold tray assembly 300 of FIG. 3. In many embodiments, the cold tray assembly 400A may include an inlet 402 and an outlet 404 configured to circulate a liquid coolant through one or more flow paths 406 defined by a plurality of baffle walls (e.g., the plurality of baffle walls 208 of FIG. 2) within a manifold tank (e.g., the manifold tank 318 of FIG. 3) of the cold tray assembly 400A.

In a variety of embodiments, the one or more flow paths 406 may be defined by the plurality of baffle walls that guide the coolant through various configurations such as, but not limited to, a serpentine flow configuration. The arrows shown in FIG. 4A depict the direction of coolant flow within the manifold tank. Although a specific configuration of the plurality of baffle walls and the one or more flow paths 406 is shown in FIG. 4A, but the disclosure is not limited to it. In one or more embodiments, there can be other configurations of the plurality of baffles walls, as discussed herein, that guide the coolant flow in different directions other than the one shown in FIG. 4A.

In a number of embodiments, the cold tray assembly 400A may be fabricated from a thermally conductive material such as aluminum or copper and may be sealed to ensure no coolant leakage during operation. In more embodiments, the manifold tank may be formed by joining an upper wall and a lower wall (for example, the upper wall 202 and the lower wall 204 of FIG. 2) using sidewalls, and the internal structure may maximize surface area exposure to the coolant, thereby increasing heat transfer efficiency from one or more components mounted on a PCB (for example, the one or more components 308 mounted on the PCB 306 of FIG. 3).

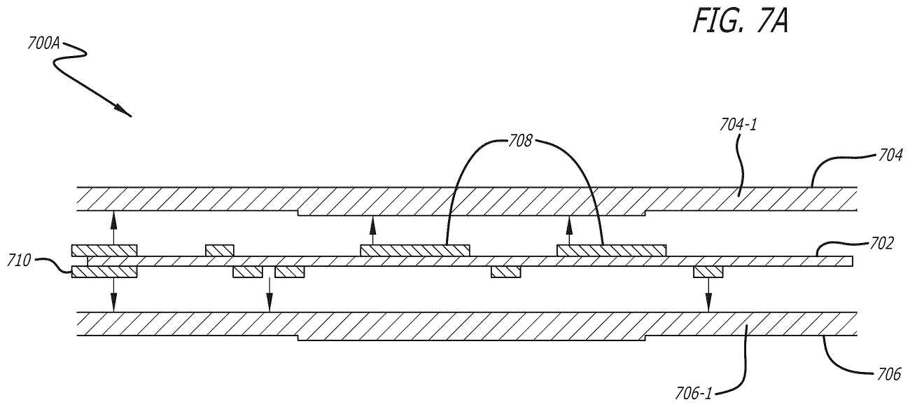

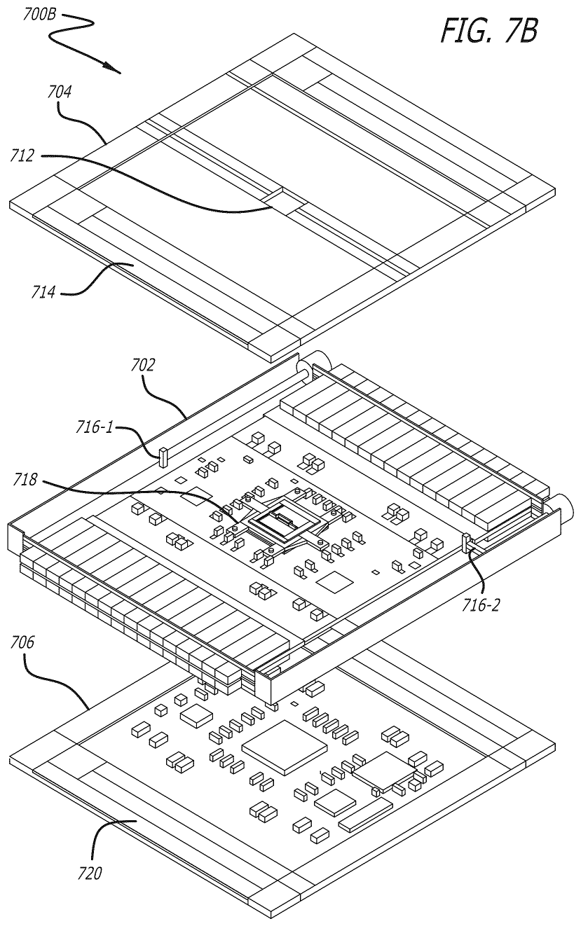

In further embodiments, the inlet 402 may be connected to an external coolant delivery system or pump, allowing for controlled coolant input into the cold tray assembly 400A. In additional embodiments, the outlet 404 may be connected to a return path in the cooling loop or to another cooling element such as an upper cold tray, in case of a dual cold tray configuration, which is explained in detail with reference to FIGS. 7A-11B.

Referring to FIG. 4B, a diagram that illustrates a coolant flow path 400B for a cold tray assembly (for example, the cold tray assembly 400A of FIG. 4A) in accordance with various embodiments of the disclosure is shown. In many embodiments, the cold tray assembly 400A may incorporate distributed liquid cooling through a network of interconnected cold plates and a planar manifold tank, optimized for compact electronic enclosures such as 1 RU line cards or server systems.

In a variety of embodiments, a liquid coolant may enter the cold tray assembly 400A via an inlet 402 and flow into an intake splitter 412. The intake splitter 412 may divide the incoming coolant stream into multiple branches for parallel delivery to cold plates thermally coupled to one or more components of a PCB, for example, pluggable optical module cages such as an upper optics cold plate 414-1 and a lower optics cold plate 414-2. The cold plates 414-1, 414-2 may be part of the cold tray thermal loop and may be integrated into the mechanical layout of the cold tray assembly 400A or directly coupled to it through tubing and thermal interface elements. In a number of embodiments, the coolant may enter the cold plates 414-1, 414-2 via a set of first ports (for example, the set of first ports 214-1, 214-2 of FIG. 2) or a second pair of coolant supply ports (for example, the second pair of coolant supply ports 314-1, 314-2 of FIG. 3).

In more embodiments, after cooling the optical modules, the warmed coolant may converge and flow downward into a manifold tank 408. In one or more embodiments, the manifold tank 408 of FIG. 4B may be similar to the manifold tank 318 of FIG. 3. In further embodiments, the manifold tank 408 may be configured to extract residual heat from one or more low-to-medium power components (for example, the one or more components 308 of FIG. 3) located across the bottom side of a PCB (for example, the PCB 306 of FIG. 3). In additional embodiments, the manifold tank 408 may be fabricated from thermally conductive metals (e.g., aluminum or copper) and configured with internal baffles or flow channels (for example, the one or more flow paths 406 of FIG. 4A) to direct the coolant in a controlled manner.

In still more embodiments, the coolant may be routed from the manifold tank 408 to a number of discrete cold plates 416-1 and 416-2, which may be thermally coupled to high-power components such as, but not limited to, ASICs mounted on the PCB. The coolant may enter the cold plates 416-1, 416-2 at an intermediate temperature (e.g., 45.5° C.) and exit after absorbing additional heat. In still further embodiments, the coolant may enter the cold plates 416-1, 416-2 via the set of first ports (for example, the set of fist ports 214-1, 214-2 of FIG. 2) or a first pair of coolant supply ports (for example, the first pair of coolant supply ports 310-1, 310-2 of FIG. 3).

In still additional embodiments, the coolant exiting the cold plates 416-1, 416-2 may be directed into an exhaust combiner 418. The exhaust combiner 418 may merge the coolant streams and direct the merged coolant stream to an outlet 404 for return to the external cooling loop. In some more embodiments, the final coolant temperature may rise to approximately 50° C. depending on the system's thermal load and coolant flow rate.

Therefore, in one or more embodiments, all liquid flow and thermal exchange occur within components of the cold tray assembly 400A. The cooling architecture may separate optic and high-power component (e.g., ASIC) cooling functions and maintain compact fluid routing and consistent flow balancing. In yet more embodiments, the intake splitter 412 and the exhaust combiner 418 may be integrated directly into the manifold tank 408.

Although a specific embodiment for a cold tray assembly 400A and a coolant flow path 400B suitable for carrying out the various steps, processes, methods, and operations described herein is discussed with respect to FIGS. 4A and 4B, any of a variety of systems and/or processes may be utilized in accordance with embodiments of the disclosure. For example, the cold tray assembly 400A may include tunable or modular baffle structures or walls that may be repositioned or replaced to adjust the coolant flow path 400B based on component placement and cooling requirements for different PCB designs. This reconfigurable flow channel approach may provide broader thermal scalability across multiple product units without requiring significant structural changes to the cold tray assembly 400A. The elements depicted in FIGS. 4A and 4B may also be interchangeable with other elements of FIGS. 1-3 and FIGS. 5-15 as required to realize a particularly desired embodiment.

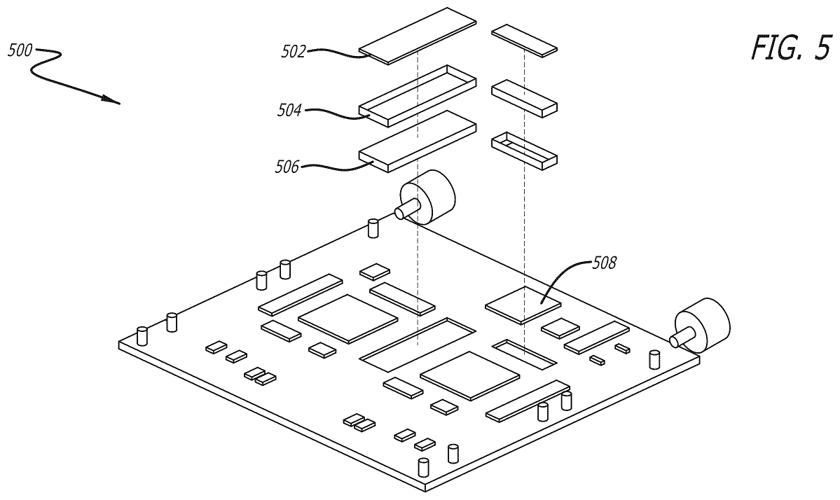

Referring to FIG. 5, a diagram that illustrates an exploded view of an upper wall 500 of a manifold tank (for example, the manifold tank 318 of FIG. 3) of a cold tray assembly (for example, the cold tray assembly 300 of FIG. 3) in accordance with various embodiments of the disclosure is shown. In many embodiments, the manifold tank of the cold tray assembly may include one or more pedestals 508 configured to thermally couple with one or more components (for example, the one or more components 308 of FIG. 3) mounted on a PCB (for example, the PCB 306 of FIG. 3).

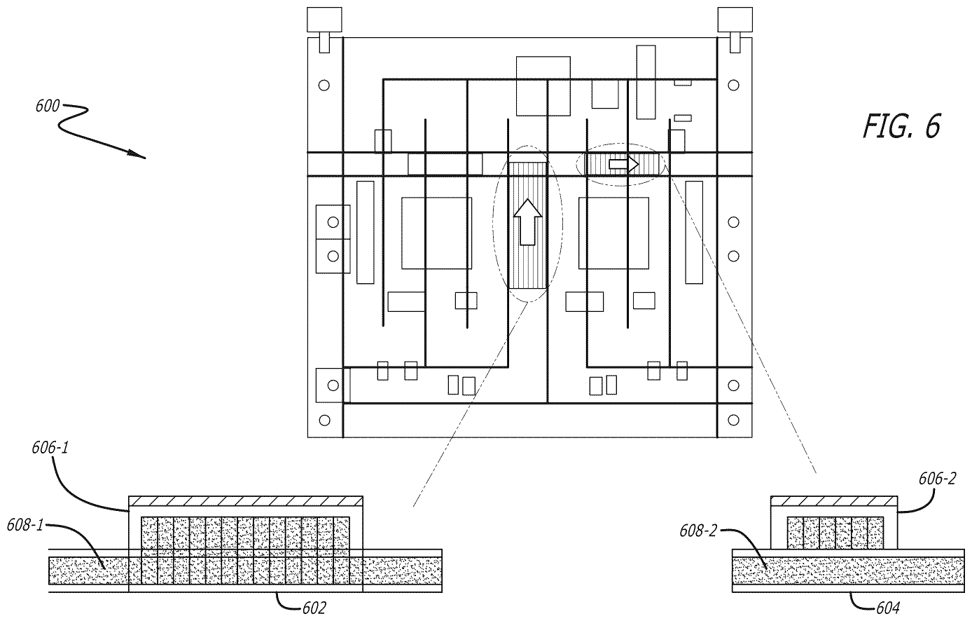

In a variety of embodiments, the pedestal 508 may correspond to a hollow pedestal. The hollow pedestal 508 may include an outer shell surround 504 that defines an internal volume for directing or receiving a liquid coolant. The coolant may flow around or through internal features, such as a set of internal or embedded fins or flow channels, within the hollow pedestal 508 to increase surface area and enhance heat exchange efficiency. The internal cooling paths may be configured in various configurations such as, but not limited to, tunnel-style or bridge-style arrangements depending on performance needs, which is explained in detail with reference to FIG. 6.

In a number of embodiments, the pedestal 508 may include a compressible TIM gap pad 502 at an exterior surface of the pedestal 508 to ensure reliable thermal contact with the corresponding PCB-mounted component. The TIM may accommodate variations in component height and mechanical tolerances, and may include phase change or thermally conductive gel materials. In more embodiments, the hollow pedestal 508 may include a thermally conductive core or heat sink core 506 or fin array inside its internal cavity, facilitating both conduction and convection-based heat transfer to the coolant circulating in the manifold tank.

In further embodiments, the pedestal 508 may be modular and interchangeable, allowing the cold tray assembly to be easily adapted to different component layouts or thermal loads of the PCB. The geometry of the pedestal 508 and internal flow pattern can also be configurable to specific heat densities. For example, taller pedestals with embedded micro fins may be used for ASICs, and wider, flatter pedestals may be used for memory devices. In additional embodiments, the overall configuration of the pedestals 508 and tubing may be optimized based on the spatial constraints and layout of the PCB, allowing for scalable deployment in systems including, but not limited to, 1 RU server systems, dense edge computing platforms, or the like.

Although a specific embodiment for a pedestal 508 suitable for carrying out the various steps, processes, methods, and operations described herein is discussed with respect to FIG. 5, any of a variety of systems and/or processes may be utilized in accordance with embodiments of the disclosure. For example, the cold tray assembly may include a hollow pedestal, a solid pedestal, or both to optimize the cooling capacity of the cold tray assembly. The elements depicted in FIG. 5 may also be interchangeable with other elements of FIGS. 1-4B and FIGS. 6-15 as required to realize a particularly desired embodiment.

Referring to FIG. 6, a diagram 600 that illustrates configurations of a hollow pedestal of a cold tray assembly (for example, the cold tray assembly 300 of FIG. 3) in accordance with various embodiments of the disclosure is shown. In many embodiments, the cold tray assembly may include a first hollow pedestal 602 and a second hollow pedestal 604. The first hollow pedestal 602 and the second hollow pedestal 604 may extend from an internal surface of a manifold tank (for example, the manifold tank 318 of FIG. 3) of the cold tray assembly.

In a variety of embodiments, the first hollow pedestal 602 may incorporate a tunnel-style fin array 606-1 comprising a set of internal fins (e.g., taller fins). The set of internal fins may protrude downward into one or more flow paths 608-1 defined by a plurality of baffle walls (for example, the plurality of baffle walls 208 of FIG. 2) of the manifold tank. The set of internal fins of the fin array 606-1 may be aligned with a direction of flow of a liquid coolant through the one or more flow paths 608-1. This alignment may enhance convective heat transfer due to the increased surface area and laminar flow conditions.

In a number of embodiments, the second hollow pedestal 604 may incorporate a bridge-style fin array 606-2 comprising a set of internal fins (e.g., shorter fins). The set of internal fins of the fin array 606-2 may terminate at a surface of the manifold tank. In the bridge-style fin array 606-2, the coolant may short-circuit across the base of the second hollow pedestal 604, for example, the set of internal fins of the fin array 606-2 may be aligned orthogonally with a direction of flow of the liquid coolant through one or more flow paths 608-2. This may enable a bypass flow mechanism for distributing cooling loads more efficiently across multiple lower-power components.

In more embodiments, the cold tray assembly may include the first hollow pedestal 602, the second hollow pedestal 604, or both, based on thermal density and power dissipation profile of one or more components mounted on a PCB. In further embodiments, the cold tray assembly may include any combination of pedestals for thermal management in dense systems, such as 1 RU server chassis or high-speed network appliances.

Although a specific embodiment for a hollow pedestal 602, 604 suitable for carrying out the various steps, processes, methods, and operations described herein is discussed with respect to FIG. 6, any of a variety of systems and/or processes may be utilized in accordance with embodiments of the disclosure. For example, the cold tray assembly may include the first hollow pedestal 602, the second hollow pedestal 604, a solid pedestal, or any combination thereof. The elements depicted in FIG. 6 may also be interchangeable with other elements of FIGS. 1-5 and FIGS. 7A-15 as required to realize a particularly desired embodiment.

Referring to FIG. 7A, a diagram that illustrates a cross-sectional view of a dual cold tray device 700A in accordance with various embodiments of the disclosure is shown. In many embodiments, the dual cold tray device 700A may include a PCB 702 positioned between a first cold tray assembly 704 (interchangeably referred to as “upper cold tray assembly 704”) and a second cold tray assembly 706 (interchangeably referred to as “lower cold tray assembly 706”). In a variety of embodiments, the first cold tray assembly 704 may be positioned on a first side of the PCB 702, for example, upper side of the PCB 702. In a number of the embodiments, the second cold tray assembly 706 may be positioned on a second side (e.g., opposite to the first side) of the PCB 702, for example, lower side of the PCB 702. Although a specific configuration for positioning of the first cold tray assembly 704 and the second cold tray assembly 706 is shown in FIG. 7A, but the disclosure is not limited to it. In one or more embodiments, the positioning of the first cold tray assembly 704 and the second cold tray assembly 706 may be reversed in other configurations, based on the thermal requirement of the PCB 702.

In more embodiments, the first cold tray assembly 704 may include a first manifold tank 704-1 that may be configured to thermally couple with one or more first components 708 mounted on the first side of the PCB 702. In further embodiments, the second cold tray assembly 706 may include a second manifold tank 706-1 that may be configured to thermally couple with one or more second components 710 mounted on the second side of the PCB 702. The first and second manifold tanks 704-1, 706-1 may be configured to circulate a liquid coolant to remove heat from various heat-generating components 708, 710 mounted on both sides of the PCB 702. For example, the first manifold tank 704-1 and the second manifold tank 706-1 may be configured to transfer heat from the one or more first components 708 and the one or more second components 710 to the liquid coolant, respectively.

In additional embodiments, the cold tray assemblies 704, 706 may enable both sides of the PCB 702 to be cooled simultaneously by independent or coordinated liquid cooling mechanisms. For example, the dual cold tray device 700A may enable each cold tray assembly 704, 706 to manage thermal loads specific to their respective side of the PCB 702. In still more embodiments, the components 708, 710 mounted to the PCB 702 may include any suitable electronic or optoelectronic component, such as but not limited to CPUs, ASICs, memory device, voltage regulators, high-speed optical transceivers, optical modules, or other power-intensive integrated circuits. In still further embodiments, the components 708, 710 may be thermally coupled to the respective cold tray assemblies 704, 706 via TIMs (for example, the TIM gap pad 502 of FIG. 5) or pedestals (for example, the pedestals 206 of FIG. 2).

In still additional embodiments, the first and second cold tray assemblies 704, 706 may be configured to have independent (or separate) liquid coolant paths or interconnected (or combined) liquid coolant paths, based on system-level thermal requirements and layout constraints. This may ensure equal or proportionate coolant distribution and pressure across both the cold tray assemblies 704, 706. The advantage of dual-sided cooling configuration may include minimized tubing requirements, reduced reliance on airflow for cooling, and enhanced thermal performance. In some more embodiments, in the separate liquid path configuration, each cold tray assembly (e.g., the first cold tray assembly 704 and the second cold tray assembly 706) may maintain a dedicated coolant loop, including independent inlet and outlet ports, enabling isolation of thermal domains and fine-grained thermal management. This may be utilized in applications where the thermal loads or coolant temperature tolerances differ between the two sides of the PCB 702, for example, if the upper cold tray assembly 704 cools the optical modules and the lower cold tray assembly 706 cools the ASICs or power regulators. In yet more embodiments, in the combined liquid path configuration, the upper and lower cold tray assemblies 704, 706 may be fluidically connected either in series or parallel. In the parallel configuration, the coolant may be split upstream and routed simultaneously to both the cold tray assemblies 704, 706, with equal pressure loss. In the series configuration, the coolant may sequentially flow through the first cold tray assembly 704 and then into the second cold tray assembly 706 (or vice versa), forming a single, continuous thermal loop. This balanced configuration may provide uniform flow distribution without active flow control components (e.g., valves or flow meters), simplifying system plumbing. After heat absorption, the coolant from both the cold tray assemblies 704, 706 may be recombined and directed to a shared exhaust path.

In still yet more embodiments, the liquid coolant flow between the first cold tray assembly 704 and the second cold tray assembly 706 may allow for selective routing, for example, the coolant may be distributed between the first cold tray assembly 704 and the second cold tray assembly 706 to prioritize high-power components or to pass through embedded cold plates before exiting, thereby optimizing thermal extraction efficiency. In many further embodiments, the dual cold tray device 700A may include one or more support columns that extend between the first cold tray assembly 704 and the second cold tray assembly 706. The one or more support columns may provide mechanical rigidity and alignment between the first cold tray assembly 704 and the second cold tray assembly 706. Further, the one or more support columns may be configured to transfer the liquid coolant between the two cold tray assemblies 704, 706 such that the first cold tray assembly 704 may be fluidically connected to the second cold tray assembly 706 via the one or more support columns.

In many additional embodiments, the one or more support columns may be configured as hollow tubular standoffs that define internal fluid passageways, permitting the circulation of the liquid coolant from one cold tray assembly to the other. For example, coolant entering the first (e.g., upper) cold tray assembly 704 may absorb heat from one or more first components 708, then flow through the hollow support columns into the second (e.g., lower) cold tray assembly 706, where additional heat may be extracted from the one or more second components 710 before the coolant exits the dual cold tray device 700A. In still yet further embodiments, the internal diameter, material composition, and surface finish of the hollow support columns may be selected to minimize pressure drop, reduce thermal resistance, and maintain balanced flow rates across both cold tray assemblies 704, 706. In still yet additional embodiments, a T-junction or nozzle fitting may be integrated at or near the entry point of the support column to split or direct flow efficiently, for example, in parallel flow configurations. In several embodiments, sealed interfaces or gaskets may be used at the T-junction where the support columns may couple to the first and second manifold tanks 704-1, 706-1, ensuring leak-proof operation under a range of pressure and temperature conditions. In several more embodiments, the one or more support columns may be strategically positioned adjacent to high-power cold plates or thermal zones, allowing the tubing runs to be shortened and simplified, thereby reducing routing complexity and system footprint.

In numerous embodiments, the first cold tray assembly 704 may be integrated on a top portion of a chassis, and the second cold tray assembly 706 may be integrated on a base on the chassis housing the PCB 702.

Although a specific embodiment for a dual cold tray device 700A suitable for carrying out the various steps, processes, methods, and operations described herein is discussed with respect to FIG. 7A, any of a variety of systems and/or processes may be utilized in accordance with embodiments of the disclosure. For example, the second cold tray assembly 706 may be functionally and structurally similar to the cold tray assembly 102 of FIG. 1. The elements depicted in FIG. 7A may also be interchangeable with other elements of FIGS. 1-6 and FIGS. 2-15 as required to realize a particularly desired embodiment.

Referring to FIG. 7B, a diagram that illustrates an exploded view of a dual cold tray device 700B in accordance with various embodiments of the disclosure is shown. In one or more embodiments, the dual cold tray device 700B of FIG. 7B may be similar to the dual cold tray device 700A of FIG. 7A. In many embodiments, the dual cold tray device 700B may include a PCB 702, a first cold tray assembly 704, and a second cold tray assembly 706. The PCB 702 may be sandwiched between the first cold tray assembly 704 and the second tray assembly 706. The first cold tray assembly 704 may include a first manifold tank 704-1 (shown in FIG. 7A) and the second cold tray assembly 706 may include a second manifold tank 706-1 (shown in FIG. 7B).

The first cold tray assembly 704 may include one or more embedded coolant flow paths and may be mounted above the PCB 702. In a variety of embodiments, the first cold tray assembly 704 may include a first fin array 714 integrated within the first manifold tank 704-1. The first fin array 714 may be configured to thermally couple with one or more first components, for example, upper-side optical cages or modules, mounted on a first side of the PCB 702. In a number of embodiments, the first cold tray assembly 704 may be integrated as a chassis lid. This may reduce system height in rackmount configurations by eliminating the need for a separate top cover.

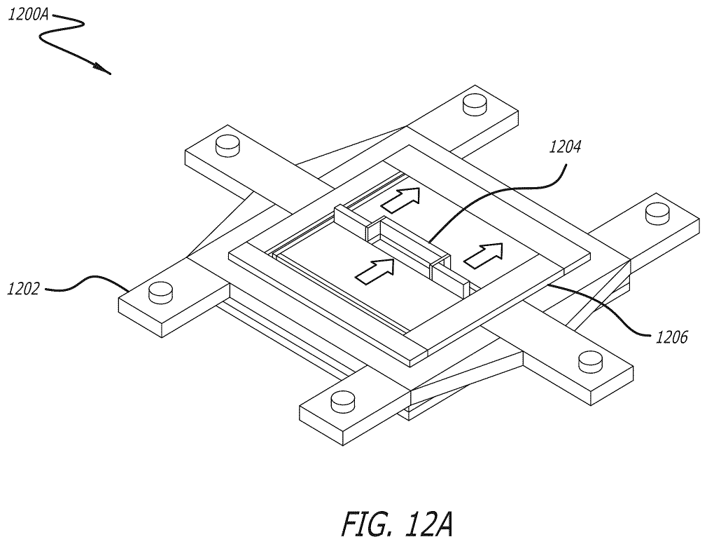

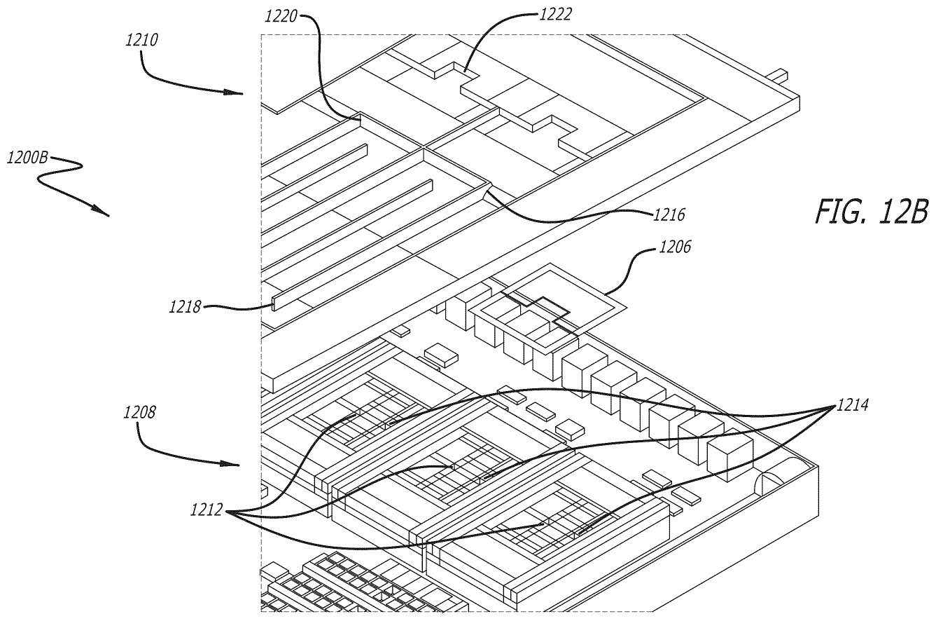

In more embodiments, the PCB 702 may support multiple high-power and low-power electronic components (e.g., ASICs, CPUs, optical transceivers, memory device, optical modules, or the like). In further embodiments, the PCB 702 may include a cold plate 718 mounted to the first side (e.g., top side) of the PCB 702. The cold plate 718 may be mounted to the PCB 702 via spring-loaded screws that interface with a thermal backing plate or heat spreader. In additional embodiments, the cold plate 718 may include a plurality of walls (shown in FIG. 12A) that surround the cold plate 718 for managing localized heat fluxes. In still more embodiments, the first cold tray assembly 704 may include a slot 712 within a surface of the first manifold tank 704-1 that faces the PCB 702. The plurality of walls surrounding the cold plate 718 may protrude into the first manifold tank 704-1 through the slot 712. In still further embodiments, the slot 712 may be configured to transfer a coolant between the first manifold tank 704-1 and the cold plate 718 to dissipate heat, from the component that may be thermally coupled to the cold plate 718, to the liquid coolant. In still further embodiments, the cold plate 718 may include a sealing component to secure the cold plate 718 to the first manifold tank 704-1. The sealing component may include, but is not limited to, a gasketed flange.

In still additional embodiments, the second cold tray assembly 706 may include a second fin array 720 integrated within the second manifold tank 706-1. The second fin array 720 may be configured to thermally couple with one or more second components, for example, optical modules, mounted on a second side (e.g., bottom side) of the PCB 702. In some more embodiments, the second cold tray assembly 706 may include one or more pedestals (for example, the one or more pedestals 206 of FIG. 2) to thermally couple with low-power components mounted on the second side of the PCB 702.

In yet more embodiments, the dual cold tray device 700B may include one or more support columns 716-1, 716-2, for example, coolant inlet and outlet T-junctions configured to route the liquid coolant through the respective cold tray assemblies 704, 706. Although a specific configuration of the dual cold tray device 700B, such as cold plate 718, slot 712, or the like, is shown in FIG. 7B, but the disclosure is not limited to it. In still yet more embodiments, the dual cold tray device 700B may be integrated as part of a line card system, where the cold tray assemblies 704, 706 provide thermal and structural functions, such as forming the faceplate or mechanical carrier. This integration may simplify system assembly, reduce part count, and enhance mechanical stability, for example, in pluggable or swappable modules.

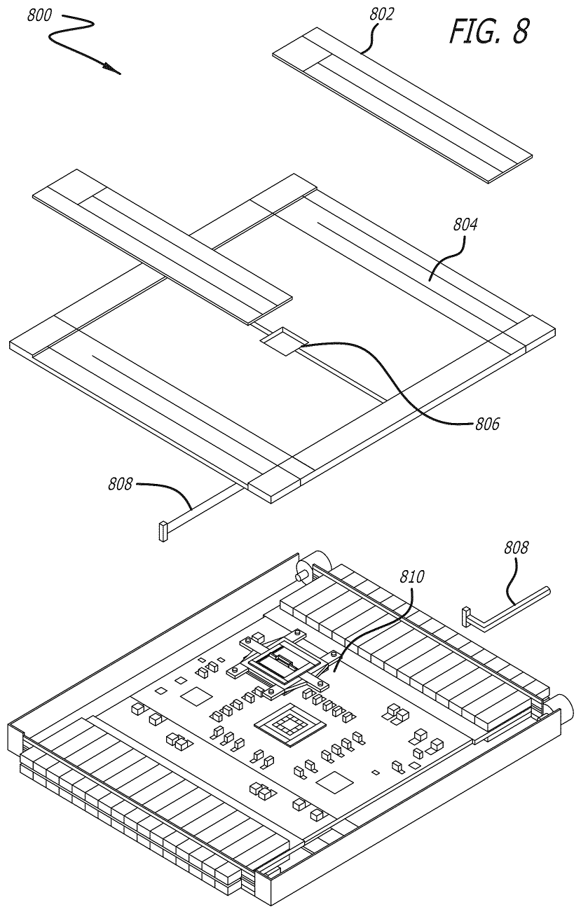

In many further embodiments, the dual cold tray device 700A, 700B may be integrated in a 1 RU 64-port single ASIC system enclosure. In one or more implementations, the system may be housed within a 21-inch wider chassis, allowing integration within standard data center rack infrastructure. The form factor may be optimized for high-density network applications. In many additional embodiments, the enclosure may be mechanically and thermally designed to support 64 optical ports, evenly distributed across the front face of the chassis. The optical ports may accommodate Octal Small Form-Factor Pluggable - eXtended Density (OSFP-XD) flattop style modules, each configured in a 1×1 cage layout. The module cages may incorporate custom riding heat sinks, which may be thermally coupled to one or more pedestals or fin structures, as discussed in greater detail in FIGS. 8-12B.

In still yet further embodiments, the rear face of the chassis may support blind mate cooling connectors to ensure efficient cooling and easy serviceability in large-scale deployments. The connectors may enable fluidic engagement and disengagement, facilitating quick swap and maintenance actions. The system may minimize the vertical and planar space occupied by liquid cooling infrastructure, preserving internal volume for flyover cabling or other board-to-board interconnects. In configurations requiring cabling, the reduced cooling footprint may enable better component layout and signal routing flexibility.

In still yet additional embodiments, components such as CPU, solid-state drive (SSD), and small-outline dual in-line memory module (SO-DIMM), used in 2 RU server systems, may be migrated from an auxiliary daughter card configuration to a consolidated footprint on the bottom surface of the main PCB 702. The spatial consolidation may reduce interconnect complexity and lower the Z-height profile, making the layout compatible with 1 RU vertical constraints. In several embodiments, the top surface of the PCB 702 may include critical high-speed digital and analog components such as FPGAs, programmable logic devices (PLDs), power inductors, or the like. In several more embodiments, power delivery components, such as, but not limited to, point-of-load field-effect transistors (POL FETs), may be redistributed to the bottom surface of the PCB 702 to free up routing area and optimize heat dissipation paths. In numerous embodiments, the system may include a CPU configuration of up to 8 cores at maximum thermal design power (TDP), ensuring support for high-performance control plane processing. Port density may be evenly distributed, with 32 ports positioned along the front edge and 32 ports along the rear edge of the chassis.

Although a specific embodiment for a dual cold tray device 700B suitable for carrying out the various steps, processes, methods, and operations described herein is discussed with respect to FIG. 7B, any of a variety of systems and/or processes may be utilized in accordance with embodiments of the disclosure. For example, the dual cold tray device 700B may include modular or scalable cold plates or slots or pedestals other than the one shown in FIG. 7B, based on power density of the components mounted on the PCB 702. In one or more embodiments, bridge-style or tunnel-style hollow pedestals may be integrated in the second cold tray assembly 706. For example, the bridge-style hollow pedestal 604 or the tunnel-style hollow pedestal 602 of FIG. 6 may be integrated to manage up to 500 Watts (W) of thermal load per component. The elements depicted in FIG. 7B may also be interchangeable with other elements of FIGS. 1-7A and FIGS. 8-15 as required to realize a particularly desired embodiment.

Referring to FIG. 8, a diagram that illustrates an exploded view of a first cold tray assembly (e.g., the first cold tray assembly 704 of FIG. 7B) and a PCB (e.g., the PCB 702 of FIG. 7B) of a dual cold tray device 800 in accordance with various embodiments of the disclosure is shown. In one or more embodiments, the dual cold tray device 800 of FIG. 8 may be similar to the dual cold tray device 700A, 700B of FIGS. 7A and 7B.

In many embodiments, the PCB may include a cold plate 810 thermally coupled to a high-power component (e.g., ASIC) mounted on the PCB. The cold plate 810 may include a plurality of walls (shown in FIG. 12A) that surround the cold plate 810. Further, the PCB may include a sealing component (e.g., gasketed flange) around the perimeter of the cold plate 810 to secure the cold plate 810 to the first cold tray assembly or to a first manifold tank (e.g., the first manifold tank 704-1 of FIG. 7A) of the first cold tray assembly. In a variety of embodiments, the cold plate 810 may include phase change TIM or gap pad TIM, selected based on component thermal load and mechanical compliance.

In a number of embodiments, the first cold tray assembly may include a first fin array 802 integrated within the first manifold tank. The first fin array 802 may be thermally coupled to a wall of the first manifold tank and located proximate to one or more components such as, but not limited to, optical transceivers or cages mounted on the PCB (for example, on the first side or upper side of the PCB). In more embodiments, the first fin array 802 may improve convective heat dissipation for edge-mounted optical modules and maintain consistent performance in compact form factors. In further embodiments, the first cold tray assembly may include a plurality of baffle walls 804 integrated with the first fin array 802. The plurality of baffle walls 804 may guide a liquid coolant to flow through the first fin array 802 and to extract heat from the one or more components of the PCB. In additional embodiments, the plurality of baffle walls 804 may define one or more flow paths in various configurations such as, but not limited to, a serpentine flow path, a radial flow path, or the like.

In some more embodiments, the first cold tray assembly may include a slot 806 corresponding to the cold plate 810 of the PCB. The plurality of walls that surround the cold plate 810 may extend into the slot 806 and the sealing component may secure the cold plate 810 to the first cold tray assembly. This way the liquid coolant may flow through the slot 806 of the first cold tray assembly into the cold plate 810 to extract heat away from the component that is thermally coupled to the cold plate 810. In yet more embodiments, the cold plate 810 may be modular, allowing for easy replacement, rework, or upgrade of thermal interface components without requiring disassembly of the full dual cold tray device 800. In still yet more embodiments, the cold plate 810 and the first manifold tank may be fabricated using composite metal alloys (e.g., copper-aluminum laminate structures) or coated with anti-corrosive or dielectric layers to ensure compatibility with advanced coolants (e.g., glycol-based or dielectric fluids) and prevent long-term material degradation. Although there is one slot 806 in the embodiment shown in FIG. 8, but the disclosure is not limited to it. In one or more embodiments, there can be more number of slots 806 in the first cold tray assembly, corresponding to the number of cold plates 810 thermally coupled to one or more components mounted on the PCB.

In many further embodiments, the dual cold tray device 800 may include one or more support columns 808, for example, coolant inlet and outlet tubing with T-junctions or splitters to distribute the liquid coolant across the dual cold tray device 800. The one or more support columns 808 may be configured to split the flow of the liquid coolant between the first cold tray assembly and a second cold tray assembly (for example, the second cold tray assembly 706 of FIGS. 7A and 7B). Therefore, the dual cold tray device 800 may minimize the need for external tubing and connectors and enable uniform coolant distribution, efficient heat rejection, and system integration simplicity.

Although a specific embodiment for a dual cold tray device 800 suitable for carrying out the various steps, processes, methods, and operations described herein is discussed with respect to FIG. 8, any of a variety of systems and/or processes may be utilized in accordance with embodiments of the disclosure. For example, although the dual cold tray device 800 corresponds to a line card architecture with optical modules mounted on both front and rear edges of the PCB, the dual cold tray device 800 may be integrated with other architectures as well such as, but not limited to, blade server architecture. The elements depicted in FIG. 8 may also be interchangeable with other elements of FIGS. 1-7B and FIGS. 9-15 as required to realize a particularly desired embodiment.

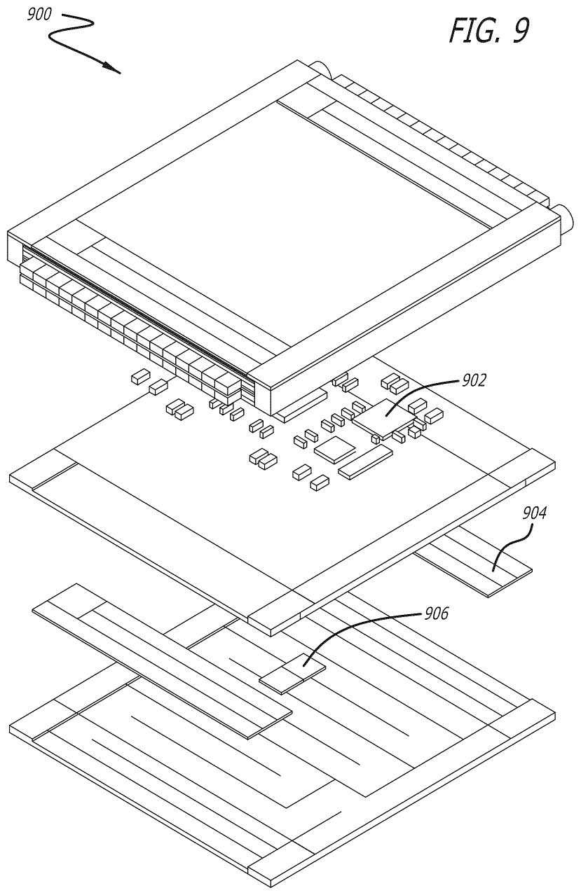

Referring to FIG. 9, a diagram that illustrates an exploded view of a second cold tray assembly (e.g., the second cold tray assembly 706 of FIG. 6B) and a PCB (e.g., the PCB 702 of FIG. 7B) of a dual cold tray device 900 in accordance with various embodiments of the disclosure is shown. In one or more embodiments, the dual cold tray device 900 of FIG. 9 may be similar to the dual cold tray device 700A, 700B of FIGS. 7A and 7B.

In many embodiments, the second (e.g., lower) cold tray assembly may include a second manifold tank (for example, the second manifold tank 706-1 of FIG. 7A). The second manifold tank may include a variety of thermal interface structures for both high-power and low-power components of the PCB. In a variety of embodiments, the second cold tray assembly may include one or more pedestals 902. The one or more pedestals 902 may include a solid pedestal, a hollow pedestal (e.g., tunnel-style hollow pedestal 602 or bridge-style hollow pedestal 604 of FIG. 6), or a combination thereof. The use of the hollow pedestal may be effective for thermal loads exceeding 500 W when combined with high-conductivity TIMs (e.g., 19 W/m·K). Further, the use of the solid pedestal may be effective for thermal loads exceeding 150 W.

In a number of embodiments, the one or more pedestals 902 may be formed from solid thermally conductive materials, such as nickel-plated aluminum or copper. The one or more pedestals 902 may be positioned at different locations on a surface of the second cold tray assembly that faces a second side (e.g., bottom side) of the PCB. In more embodiments, the one or more pedestals 902 may directly interface with corresponding components on the PCB. To improve thermal transfer and account for component height variations, the one or more pedestals 902 may include a compressible TIM, in the form of a gap pad. This may enable low-force thermal conduction with minimal mechanical stress on the board or components.

In further embodiments, the second cold tray assembly may include a second fin array 904 integrated within the second manifold tank. For example, the second fin array 904 may be positioned along the periphery of the second cold tray assembly. In additional embodiments, the second fin array 904 may be configured to thermally couple with one or more components (e.g., the one or more components 710 of FIG. 7A) mounted on the PCB such as, but not limited to, optical modules mounted on the front and rear edges on the second side of the PCB. The placement of the second fin array 904 may ensure that high-density components are adequately cooled without requiring additional heatsinks or localized airflow mechanisms.

In some more embodiments, the second cold tray assembly may include a plurality of baffle walls (e.g., the plurality of baffle walls 208 of FIG. 2) within the second manifold tank. The plurality of baffle walls may define one or more flow paths (e.g., a serpentine flow path) to guide the flow of a liquid coolant through the second manifold tank and ensure uniform heat extraction across the PCB. Although a specific configuration of serpentine flow path is shown in the embodiment of FIG. 9, but the disclosure is not limited to it. In one or more embodiments, the serpentine flow path may enable flexible placement of the one or more pedestals 902 and ensure that all active zones of the PCB receive coolant exposure, irrespective of layout variations.

In yet more embodiments, the second cold tray assembly may include a fin stack 906 in the second manifold tank. For example, the fin stack 906 may be positioned directly beneath high-power components of the PCB such as, but not limited to, ASICs. Therefore, if an ASIC is positioned at the center of the PCB, a first cold tray assembly (e.g., the first cold tray assembly 704 of FIG. 7B) may include a slot (e.g., the slot 806) at the center of a first manifold tank, and the second cold tray assembly may include the fin stack 906 positioned at the center of the second manifold tank. In still yet more embodiments, the dual cold tray device 900 may include internal support fins under large components to regulate flow between the first cold tray assembly and the second cold tray assembly, maintaining thermal symmetry and consistent hydraulic performance. In many further embodiments, the second cold tray assembly may be integrated at a base of a chassis housing the PCB.

Although a specific embodiment for a dual cold tray device 900 suitable for carrying out the various steps, processes, methods, and operations described herein is discussed with respect to FIG. 9, any of a variety of systems and/or processes may be utilized in accordance with embodiments of the disclosure. For example, the second cold tray assembly may include any number of fin stacks 906 based on one or more cold plates thermally coupled to one or more high-power components of the PCB. The elements depicted in FIG. 9 may also be interchangeable with other elements of FIGS. 1-8 and FIGS. 10A-15 as required to realize a particularly desired embodiment.

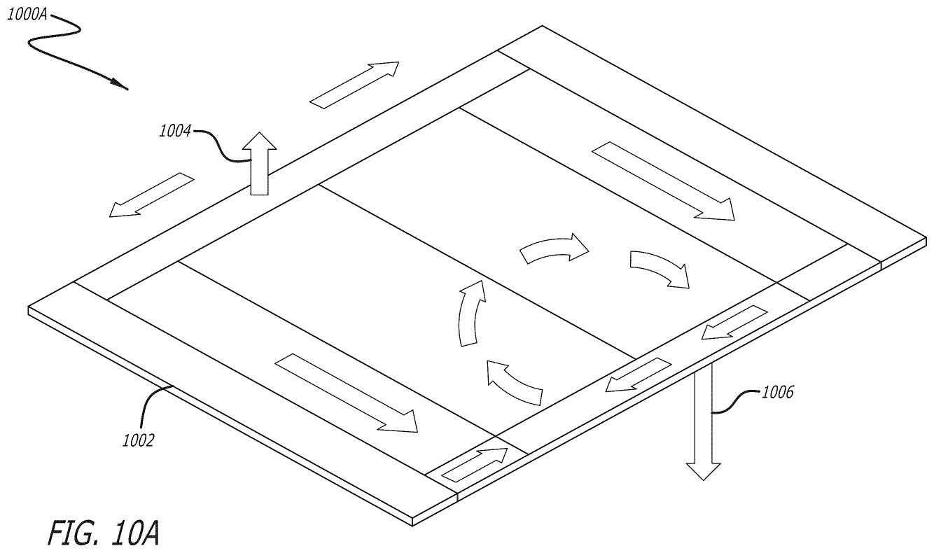

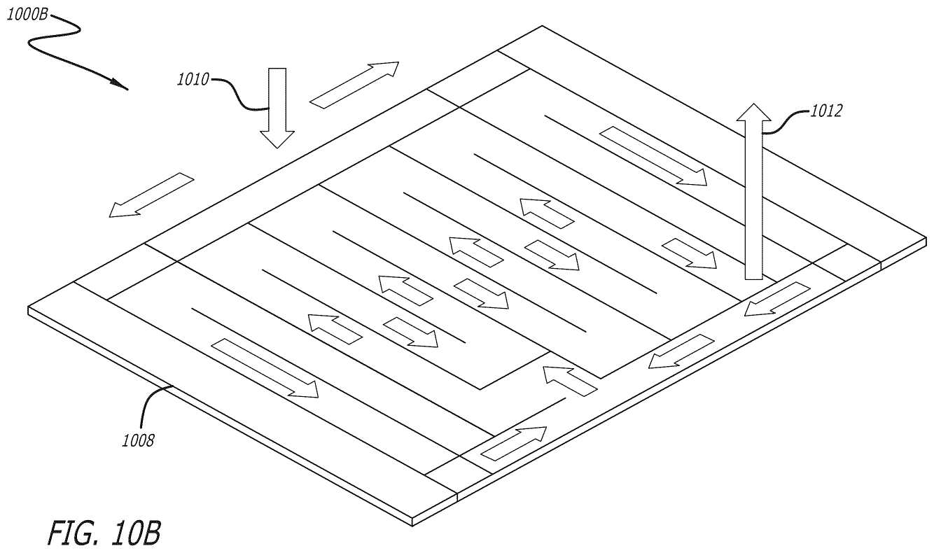

Referring to FIG. 10A, a diagram that illustrates a perspective view of a coolant flow path 1000A of a first cold tray assembly 1002 of a dual cold tray device (for example, the dual cold tray device 800 of FIG. 8) in accordance with various embodiments of the disclosure is shown. In one or more embodiments, the first cold tray assembly 1002 may be similar to the first cold tray assembly 704 of FIG. 7B. In many embodiments, the dual cold tray device may include an inlet 1004. The inlet 1004 may be configured to receive a coolant into the first cold tray assembly 1002. As represented by the arrows in FIG. 10A, the coolant may enter a first manifold tank (e.g., the first manifold tank 704-1 of FIG. 7A) of the first cold tray assembly 1002 from the inlet 1004, where the coolant may be split evenly across two mirrored halves of the first cold tray assembly 1002. The coolant may travel laterally through designated flow paths or channels, guided by the internal geometry and a plurality of baffle walls of the first manifold tank. As discussed herein, the plurality of baffle walls may guide the coolant across the interior surface of the first cold tray assembly 1002, ensuring consistent exposure to heat-generating components mounted on a first side of a PCB (e.g., the PCB 702 of FIG. 7B).

In a number of embodiments, after traveling through first fin array (e.g., the first fin array 802 of FIG. 8) and a slot (e.g., the slot 806 of FIG. 8), and absorbing heat from the components thermally coupled to the first cold tray assembly 1002, the coolant may reconverge at the opposite edge of the first cold tray assembly 1002. The heated coolant may exit or eject from the first cold tray assembly 1002 via an outlet 1006 and continue downstream in the cooling loop.

In a variety of embodiments, the coolant flow path 1000A may be optimized for pressure symmetry. For example, a total coolant flow rate may be 4.3 Liters per Minute with a total pressure drop of 42.1 kPa across the entire path. This configuration may eliminate the need for external valving or active flow control, simplifying the fluid routing and minimizing interconnect complexity. Further, this configuration may reduce external plumbing and maintain efficient heat extraction from both active compute elements and edge-mounted optical components of the PCB.

Referring to FIG. 10B, a diagram that illustrates a perspective view of a coolant flow path 1000B of a second cold tray assembly 1008 of a dual cold tray device (for example, the dual cold tray device 900 of FIG. 9) in accordance with various embodiments of the disclosure is shown. In one or more embodiments, the second cold tray assembly 1008 may be similar to the second cold tray assembly 706 of FIG. 7B. In many embodiments, the dual cold tray device may include an inlet 1010 to receive a coolant into a second manifold tank (e.g., the second manifold tank 706-1 of FIG. 7A) of the second cold tray assembly 1008.

Upon entering the second manifold tank, one or more flow paths may guide the coolant to flow through the second cold tray assembly 1008. Once heat transfer has occurred throughout the footprint of the second cold tray assembly 1008, the heated coolant may exit via an outlet 1012. This configuration may support hydraulic balance between the first cold tray assembly 1002 and the second cold tray assembly 1008 of the dual cold tray device by maintaining similar pressure drop profiles and matched thermal loads.

Therefore, by utilizing cold plates and cold tray assemblies directly into the structural elements of a chassis, the pressure drop throughout the fluidic loop may be drastically reduced. In a number of embodiments, around 50% or greater reduction in cooling distribution unit pumping power may be achieved by way of the dual cold tray device, thereby enhancing energy efficiency and maintaining coolant flow across all thermally active zones. The simplification of fluid connections may enhance manufacturability and improve reliability. The reduction in the number of fluid coupling interfaces may minimize the probability of leaks and pressure instabilities. In additional implementations, optical module cost per port may be minimized by limiting hardware customization. For example, the design may include standard 1×1 riding heat sink cages for OSFP-XD modules, requiring the removal of cooling fins and the adoption of weaker leaf spring clips, thereby avoiding complex transceiver cage redesigns, and preserving economies of scale and supply chain flexibility. In one or more implementations, the architecture may be scalable for a wide range of next-generation switch and router deployments.

Although a specific embodiment for coolant flow paths 1000A, 1000B suitable for carrying out the various steps, processes, methods, and operations described herein is discussed with respect to FIGS. 10A and 10B, any of a variety of systems and/or processes may be utilized in accordance with embodiments of the disclosure. For example, the inlets 1004, 1010 and the outlets 1006, 1012 of the respective first cold tray assembly 1002 and the second cold tray assembly 1008 may be routed to corresponding support columns or coolant inlet and outlet tubing with T-junctions (for example, the support columns 808 of FIG. 8) to enable optimized flow of coolant between the first cold tray assembly 1002 and the second cold tray assembly 1008. The elements depicted in FIGS. 10A and 10B may also be interchangeable with other elements of FIGS. 1-9 and FIGS. 11A-15 as required to realize a particularly desired embodiment.

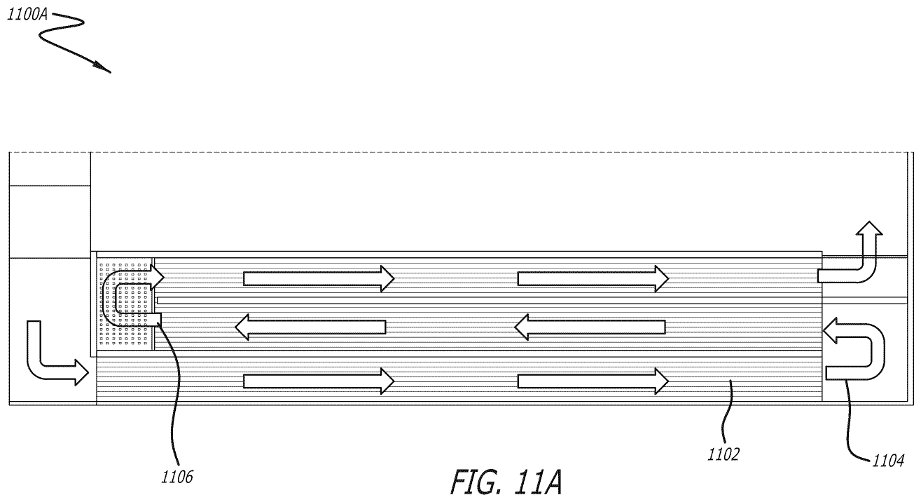

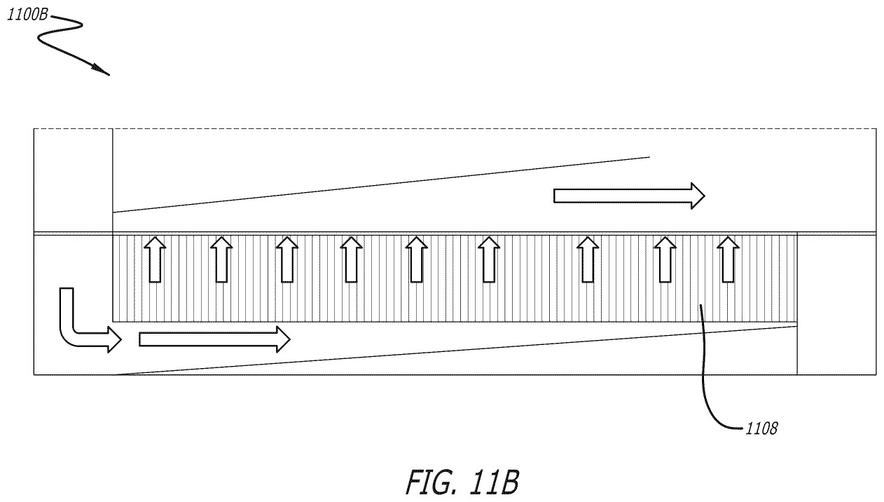

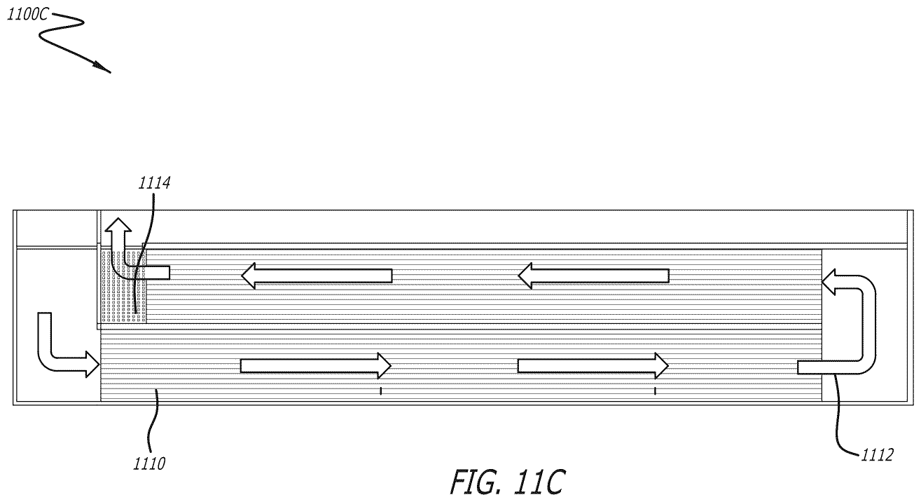

Referring to FIG. 11A, a diagram that illustrates a first top-down view of a fin array 1100A of a dual cold tray device (e.g., the dual cold tray device 700A, 700B of FIGS. 7A and 7B) in accordance with various embodiments of the disclosure is shown. In many embodiments, the fin array 1100A may correspond to a first fin array of a first cold tray assembly (e.g., the first fin array 802 of FIG. 8), a second fin array of a second cold tray assembly (e.g., the second fin array 904 of FIG. 9), or both.

In a variety of embodiments, a coolant may follow a serpentine flow path (as shown by arrows in FIG. 11A) within a manifold tank of a cold tray assembly. The coolant may enter the manifold tank through an inlet, travel through a number of (e.g., three) separate linear flow channels 1102, and make two U-turns 1104, 1106 internally to ensure full coverage across the fin array 1100A. In a number of embodiments, the fin array 1100A may include alternating fin structures aligned perpendicular to a direction of flow of the coolant, enhancing turbulent mixing and maximizing heat transfer efficiency. At a first U-turn 1104, the coolant may reverse the direction from a first flow channel to a second flow channel. A second U-turn 1106 may occur after the second pass, directing the coolant into a third flow channel, where the coolant may exit the fin array 1100A toward an outlet manifold.

In more embodiments, the U-turns 1104, 1106 may correspond to rounded bends to minimize pressure drop and prevent flow stagnation. The integrated fin array 1100A and manifold structure may be configurable for even temperature distribution across all optical small form-factor pluggable (OSFP) modules. In one or more implementations, the modules may dissipate power levels around 25 W per module.

In further embodiments, the pattern of the fin array 1100A may ensure that the coolant flows through the entire surface area of the fin array 1100A, enabling consistent thermal management and less than, for example, 3° C. thermal variation across the fin array 1100A.

In additional embodiments, at the second U-turn 1106, the fin array 1100A may include a curved fin structure. This may enable a smooth redirection of coolant flow, lowering the pressure loss associated with directional changes and improving flow continuity.

Referring to FIG. 11B, a diagram that illustrates a second top-down view of a fin array 1100B of a dual cold tray device (e.g., the dual cold tray device 700A, 700B of FIGS. 7A and 7B) in accordance with various embodiments of the disclosure is shown. In many embodiments, the fin array 1100B may correspond to a first fin array of a first cold tray assembly (e.g., the first fin array 802 of FIG. 8), a second fin array of a second cold tray assembly (e.g., the second fin array 904 of FIG. 9), or both.

In a variety of embodiments, a coolant may enter a manifold tank of a cold tray assembly. Upon entry, the coolant may travel in a straight lateral path over an array of vertically aligned fins 1108, which extend upward from the base of the cold tray assembly. The fins 1108 may be arranged to create multiple parallel channels that allow the coolant to evenly distribute across the width of an optical cage area. As the coolant flows laterally, the upward-pointing arrows represent vertical heat transfer across the fin array 1100B, where heat may be drawn away from optical modules and dissipated into the coolant stream.

In a number of embodiments, the fin array 1100B may be configured in a ramped base geometry, for example, depth of the fins 1108 increasingly gradually from front to rear, to enable uniform lateral coolant distribution, and ensure consistent cooling performance along the entire length of the flow path. The flow eventually turns at the end of the cold tray assembly, exiting through an outlet.

In more embodiments, a vapor chamber base may be used to supplement the design of the fin array 1100B. The vapor chamber structure can enhance heat spreading and improve fin efficiency by distributing thermal energy more evenly across the broader fin base. In further embodiments, the fin array 1100B may provide lower pressure drop and an even lateral flow profile, simplifying the manifold layout and coolant routing within the cold tray assembly.

Referring to FIG. 11C, a diagram that illustrates a third top-down view of a fin array 1100C of a dual cold tray device (e.g., the dual cold tray device 700A, 700B of FIGS. 7A and 7B) in accordance with various embodiments of the disclosure is shown. In many embodiments, the fin array 1100C may correspond to a first fin array of a first cold tray assembly (e.g., the first fin array 802 of FIG. 8), a second fin array of a second cold tray assembly (e.g., the second fin array 904 of FIG. 9), or both. The configuration shown in FIG. 11C may be optimized for a dual-pass counterflow pattern. In many embodiments, a coolant may flow through a number of (e.g., two) separate linear flow channels 1110, and make one U-turn 1112 internally to ensure full coverage across the fin array 1100C.

In a number of embodiments, the fin array 1100C may include curved fins 1114 at the end of the fin array 1100C to reduce pressure drop during the turning flow and to maintain high flow velocity. In a variety of embodiments, the dual-pass counterflow fin array 1100C may ensure that all components, whether upstream or downstream, are exposed to uniform coolant temperatures. In more embodiments, the coolant may enter from the left side, flow horizontally across fins over a first flow channel, turn around through the U-turn 1112, and flow in a reverse direction over a second flow channel before exiting through the curved fins 1114. The use of curved or gradually transitioning fins 1114 may minimize flow separation and turbulence, enabling stable flow dynamics even at higher flow rates (e.g., 3-6 Liters per Minute).

Although a specific embodiment for fin arrays 1100A, 1100B, 1100C suitable for carrying out the various steps, processes, methods, and operations described herein is discussed with respect to FIGS. 11A, 11B, and 11C, any of a variety of systems and/or processes may be utilized in accordance with embodiments of the disclosure. For example, a combination of the fin arrays 1100A, 1100B, 1100C may be utilized in the first cold tray assembly and the second cold tray assembly based on the thermal layout of the PCB. In additional examples, configurations of fin arrays 1100A, 1100B, 1100C other than the one shown in FIGS. 11A, 11B, and 11C are possible based on the thermal layout of the PCB to optimize the cooling capacity of the cold tray assemblies. The elements depicted in FIGS. 11A, 11B, and 11C may also be interchangeable with other elements of FIGS. 1-10B and FIGS. 12A-15 as required to realize a particularly desired embodiment.

Referring to FIG. 12A, a diagram that illustrates a perspective view 1200A of a cold plate 1202 for a component (e.g., ASIC) mounted on a PCB (e.g., the PCB 702 of FIG. 7A) in accordance with various embodiments of the disclosure is shown. In many embodiments, the cold plate 1202 may be configured to mount onto a PCB and interface thermally with a high-power component such as ASIC. The cold plate 1202 may provide localized, high-efficiency heat extraction for critical components mounted on the PCB.

In a variety of embodiments, the cold plate 1202 may include a plurality of walls 1204 that surround the cold plate 1202. The plurality of walls 1204 may be located on a lid of the cold plate 1202. In a number of embodiments, the plurality of walls 1204 may protrude upward into a slot (for example, the slot 806 of FIG. 8) of a first cold tray assembly (for example, the first cold tray assembly 704 of FIG. 7B). The plurality of walls 1204 may function as an internal fluid partition that defines discrete inlet and outlet flow zones within the cold plate 1202, ensuring directional control of a coolant through thermal transfer surfaces. In more embodiments, the coolant may enter through the slot, flow laterally across the thermal interface region, and exit via side outlet passages, as indicated by directional arrows shown in FIG. 12A.

In further embodiments, the cold plate 1202 may include a sealing component 1206 around a perimeter of the cold plate 1202. The sealing component 1206 may include a gasketed flange that may ensure a secure and leak-proof connection against a lower surface of the first cold tray assembly. In additional embodiments, additional gaskets may be positioned along vertical edges of the plurality of walls 1204 to further isolate inlet and outlet streams and avoid fluid bypass across the partition. The gasketing configurations may eliminate the need for external fittings and reduce assembly complexity. In some more embodiments, the cold plate 1202 may be spring-mounted to the PCB using, but not limited to, screws and backplates.

Referring to FIG. 12B, a diagram that illustrates an exploded view of a cold tray device 1200B integrating one or more cold plates (e.g., the cold plate 1202 of FIG. 12A) for one or more high-power components mounted on a PCB 1208 in accordance with various embodiments of the disclosure is shown. In one or more implementations, the cold tray device 1200B may be configured as a dual cold tray device (for example, the dual cold tray device 700A of FIG. 7A). In more implementations, the cold tray device 1200B may be configured to include an upper cold tray assembly 1210 on top of the PCB 1208. In many embodiments, one or more cold plates may be thermally coupled to high-power components mounted on the PCB 1208 comprising an inlet 1212 and an outlet 1214. The high-power components may include, but are not limited to, ASICs, GPUs, or the like.

In a variety of embodiments, the cold tray device 1200B may include the PCB 1208, configured with multiple discrete high-power processing components (e.g., GPUs), and the cold tray assembly 1210 positioned above the PCB 1208. In a number of embodiments, the cold tray assembly 1210 may include a manifold tank integrated with a plurality of baffle walls (1216, 1218, 1220) defining one or more flow paths that guide a coolant to flow in a controlled manner over. In more embodiments, the baffle walls 1216, 1220 may have a closed end, and the baffle wall 1218 may have an open end defining the one or more flow paths (e.g., a serpentine flow path) to direct the coolant in a controlled manner. In the embodiment shown in FIG. 12B, the baffle wall 1216 comprises a curved closed end and the baffle wall 1220 comprises a closed end that is perpendicular to a surface of the manifold tank. As discussed herein, there may be various configurations of the plurality of baffle walls (1216, 1218, 1220) other than the one shown in FIG. 12B. For example, the plurality of baffle walls (1216, 1218, 1220) may define a radial flow path.

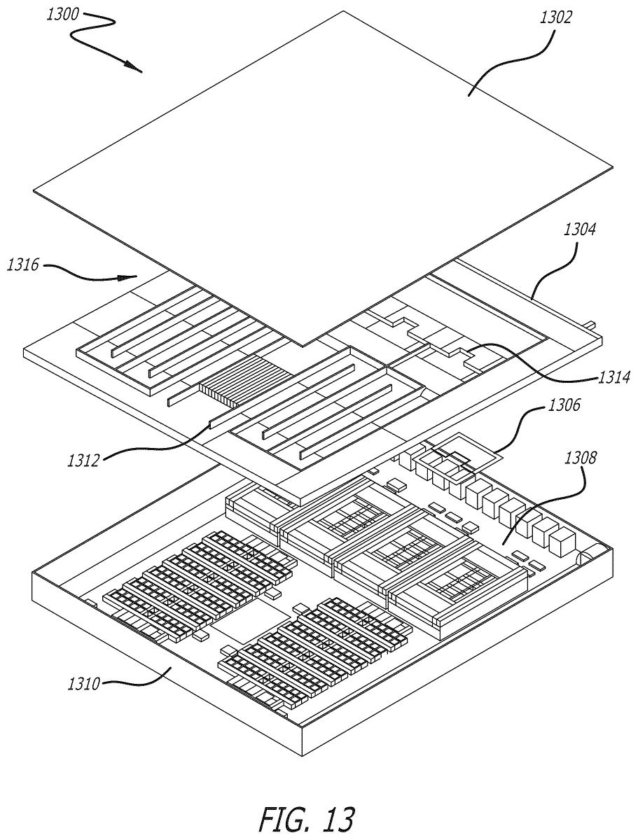

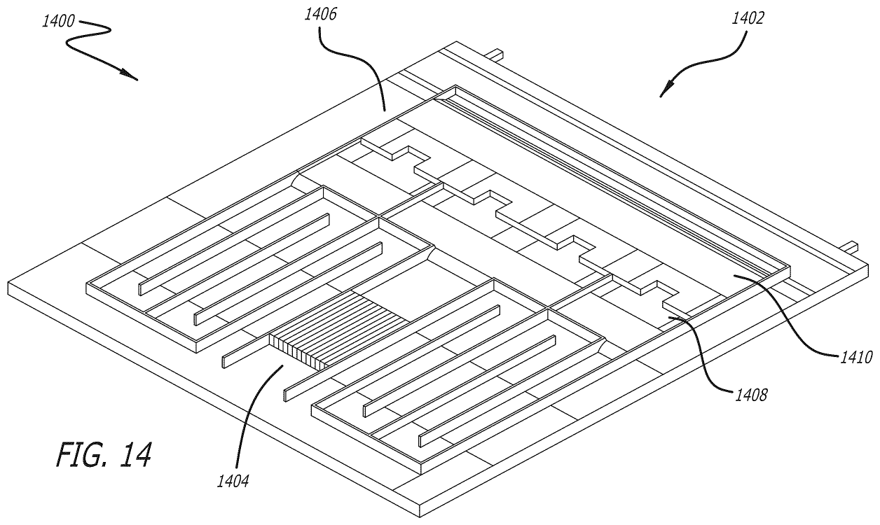

In further embodiments, the cold tray assembly 1210 may include one or more slots surrounded with walls 1222. The one or more slots may correspond to one or more cold plates thermally mounted on the PCB 1208, which is explained in further detail with reference to FIGS. 13 and 14.

In additional embodiments, the one or more cold plates may include a sealing component 1206, e.g., gasketed flange 1206 at its outer perimeter. The gasketed flange 1206 may provide robust sealing against the lower surface of the cold tray assembly 1210, ensuring isolated and leak-proof fluid zones. In more embodiments, the one or more cold plates may include the inlet 1212 and the outlet 1214, enabling parallel routing of coolant across all discrete cold plates.

Although a specific embodiment for a cold plate 1202 suitable for carrying out the various steps, processes, methods, and operations described herein is discussed with respect to FIGS. 12A and 12B, any of a variety of systems and/or processes may be utilized in accordance with embodiments of the disclosure. For example, the sealing component used to secure the cold plate 1202 to the cold tray assembly 1210 may include, but is not limited to, O-rings, foam-in-place seals, or the like, and may not be limited to the gasketed flange 1206. The elements depicted in FIGS. 12A and 12B may also be interchangeable with other elements of FIGS. 1-11B and FIGS. 13-15 as required to realize a particularly desired embodiment.

Referring to FIG. 13, is a diagram that illustrates an exploded view of a cold tray device 1300 comprising a cold tray assembly 1316 and a PCB 1310 in accordance with various embodiments of the disclosure is shown. In many embodiments, the cold tray assembly 1316 may be configured for thermal management for one or more heat-generating components mounted on the PCB 1310. For example, the cold tray assembly 1316 may be configured on top of the PCB 1310. In a number of embodiments, as the one or more components operate, heat may be transferred from the one or more components into a liquid coolant flowing through the cold tray assembly 1316. In a variety of embodiments, the cold tray assembly 1316 may be integrated into a lid of a chassis housing the PCB 1310.

In more embodiments, the cold tray assembly 1316 may be configured to support high-density computing platforms including quad GPU compute cards integrated within a 1 OU (48 mm height) enclosure. In additional examples, the thermal load of the PCB 1310 may include four GPU modules, each dissipating approximately 893 W, and one CPU dissipating approximately 500 W, resulting in a total power dissipation of around 4608 W.

In further embodiments, the liquid coolant used within the cold tray assembly 1316 may operate at an inlet temperature of approximately 45° C., corresponding to the ambient temperature inside a high-performance data center environment. The cooling loop may be configured for a flow rate of approximately 6.9 Liters per Minute to ensure convective heat transfer from all compute modules to the coolant.

In additional embodiments, the layout of the compute card may be such that the four GPU modules may be arranged in parallel rows with pedestals or cold plates coupled directly to their heat spreaders. The CPU module may be centrally located and thermally coupled to a separate high-efficiency cooling interface.

In many embodiments, the cold tray assembly 1316 may include a manifold tank 1304. The manifold tank 1304 may include a plurality of baffle walls 1312 defining one or more flow paths for guiding a coolant through the cold tray assembly 1316. In one or more embodiments, the plurality of baffle walls 1312 may be similar to the plurality of baffle walls 208 of FIG. 2. In a variety of embodiments, the cold tray assembly 1316 may include a manifold tank lid 1302. The manifold tank lid 1302 may function as a cover for a chassis.

In a number of embodiments, the cold tray assembly 1316 may include one or more slots 1314 within a surface of the manifold tank 1304. The one or more slots 1314 may correspond to one or more cold plates 1308 thermally coupled to one or more components (e.g., GPUs) on the PCB 1310. The one or more slots 1314 may be configured to transfer the coolant between the manifold tank 1304 and the one or more cold plates 1308 to dissipate heat from the one or more components to the coolant.

In more embodiments, the PCB 1310 may include a sealing component 1306, such as, a gasketed flange. The sealing component 1306 may surround the one or more cold plates 1308 to provide mechanical isolation and fluid sealing between the top and bottom surfaces of the manifold tank 1304.

Although a specific embodiment for a cold tray assembly 1316 suitable for carrying out the various steps, processes, methods, and operations described herein is discussed with respect to FIG. 13, any of a variety of systems and/or processes may be utilized in accordance with embodiments of the disclosure. For example, the cold tray assembly 1316 may include fluidically isolated thermal zones with dedicated flow splitters and exhaust combiners to segment and balance the coolant flow, reducing cross-component thermal interference. The elements depicted in FIG. 13 may also be interchangeable with other elements of FIGS. 1-12B and FIGS. 14-15 as required to realize a particularly desired embodiment.

Referring to FIG. 14, a diagram that illustrates a perspective view of a cold tray assembly 1400 in accordance with various embodiments of the disclosure is shown. In one or more embodiments, the cold tray assembly 1400 of FIG. 14 may be similar to the cold tray assembly 1316 of FIG. 13. In many embodiments, the cold tray assembly 1400 may be configured on top of a PCB (for example, the PCB 1310 of FIG. 13).

In a variety of embodiments, the cold tray assembly 1400 may include a manifold tank 1402. The manifold tank 1402 may include one or more pedestals 1404. In a number of embodiments, the one or more pedestals 1404 may include a hollow pedestal with a set of internal fins, a solid pedestal, or both. The hollow pedestal may correspond to a tunnel-style hollow pedestal 602, a bridge-style hollow pedestal 604, or both (shown in FIG. 6). In one or more examples, the flow of liquid coolant through the hollow pedestal may be 3.7 Liters per Minute. In additional examples, the inlet coolant temperature may be around 45.5° C. In many examples, the pedestal 1404 may include a TIM with thermal conductivity of 19 W/m·K and a bond line thickness of 1 mm. The interface temperature may be around 75° C., indicating effective heat removal in a high thermal resistance interface condition.

In more embodiments, the cold tray assembly 1400 may include an inlet 1406 and an outlet 1410. A coolant may enter the manifold tank 1402 from the inlet 1406 and exit from the manifold tank 1402 via the outlet 1410. The coolant may travel through a plurality of baffle walls 1408 defining one or more flow paths within the manifold tank 1402. In the embodiment shown in FIG. 14, one or more slots (e.g., the one or more slots 1314 of FIG. 13) may be defined by the plurality of baffle walls 1408 to correspond to one or more cold plates (e.g., the one or more cold plates 1308 of FIG. 13) mounted on the PCB. In further embodiments, the cold tray assembly 1400 may be contoured with entry and exit ramps to accommodate the flat-topped profile of the one or more cold plates. This reduction in volume may improve space utilization within the tight vertical constraints of a 1 OU chassis.

Although a specific embodiment for a cold tray assembly 1400 suitable for carrying out the various steps, processes, methods, and operations described herein is discussed with respect to FIG. 14, any of a variety of systems and/or processes may be utilized in accordance with embodiments of the disclosure. For example, the cold tray assembly 1400 may include additional ports for guiding the coolant to other components of the PCB. The elements depicted in FIG. 14 may also be interchangeable with other elements of FIGS. 1-13 and FIG. 15 as required to realize a particularly desired embodiment.

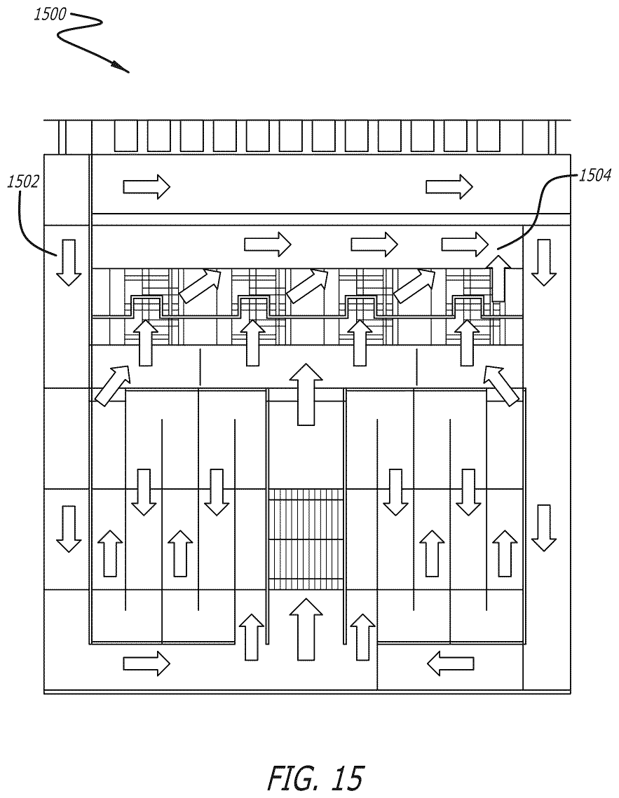

Referring to FIG. 15, a top-down schematic view of a coolant flow path 1500 of a cold tray assembly (for example, the cold tray assembly 1400 of FIG. 14) in accordance with various embodiments of the disclosure is shown. In many embodiments, the arrows shown in FIG. 15 may denote a direction of flow of a liquid coolant across different functional regions within the cold tray assembly. The coolant flow path 1500 may be optimized to enable uniform and efficient heat dissipation from different high-power and auxiliary components housed within a PCB.

In a number of embodiments, the coolant may enter the cold tray assembly via an inlet 1502 and follow a lateral flow across the cold tray assembly. The coolant may exit from the cold tray assembly via an outlet 1504. In one or more embodiments, the inlet 1502 and the outlet 1504 of FIG. 15 may be similar to the respective inlet 1406 and outlet 1410 of FIG. 14.

In more examples, the cold tray assembly may accommodate a total pressure drop of around 24 kPa (e.g., around 5 kPa at the cold plate and around 18.6 kPa at the main cold tray assembly structure) from the inlet 1502 to the outlet 1504. Therefore, around 65% reduction in pressure drop is achieved from conventional systems.

Although a specific embodiment for a coolant flow path 1500 suitable for carrying out the various steps, processes, methods, and operations described herein is discussed with respect to FIG. 15, any of a variety of systems and/or processes may be utilized in accordance with embodiments of the disclosure. For example, the cold tray assembly may include integrated fin arrays located proximate to one or more components of the PCB to guide the coolant through the integrated fin arrays. The elements depicted in FIG. 15 may also be interchangeable with other elements of FIGS. 1-14 as required to realize a particularly desired embodiment.

Although the present disclosure has been described in certain specific aspects, many additional modifications and variations would be apparent to those skilled in the art. In particular, any of the various configurations described above are possible in alternative sequences and/or in parallel (on the same or on different computing devices) in order to achieve similar results in a manner that is more appropriate to the requirements of a specific application. It is therefore to be understood that the present disclosure can be practiced other than specifically described without departing from the scope and spirit of the present disclosure. Thus, embodiments of the present disclosure should be considered in all respects as illustrative and not restrictive. It will be evident to the person skilled in the art to freely combine several or all of the embodiments discussed here as deemed suitable for a specific application of the disclosure. Throughout this disclosure, terms like “advantageous,” “exemplary,” or “example” indicate elements or dimensions which are particularly suitable (but not essential) to the disclosure or an embodiment thereof and may be modified wherever deemed suitable by the skilled person, except where expressly required. Accordingly, the scope of the disclosure should be determined not by the embodiments illustrated, but by the appended claims and their equivalents.

Any reference to an element being made in the singular is not intended to mean “one and only one” unless explicitly so stated, but rather “one or more.” All structural and functional equivalents to the elements of the above-described preferred embodiment and additional embodiments as regarded by those of ordinary skill in the art are hereby expressly incorporated by reference and are intended to be encompassed by the present claims.

Moreover, no requirement exists for a system or method to address each and every problem sought to be resolved by the present disclosure, for solutions to such problems to be encompassed by the present claims. Furthermore, no element, component, or method step in the present disclosure is intended to be dedicated to the public regardless of whether the element, component, or method step is explicitly recited in the claims. Various changes and modifications in form, material, workpiece, and fabrication material detail can be made, without departing from the spirit and scope of the present disclosure, as set forth in the appended claims, as might be apparent to those of ordinary skill in the art, are also encompassed by the present disclosure.

What is claimed is:

1. A cold tray assembly mounted to a printed circuit board (PCB), the cold tray assembly comprising:
a manifold tank;
one or more pedestals that extend outward from the manifold tank, the one or more pedestals configured to thermally couple with one or more components of the PCB; and
a plurality of baffle walls within the manifold tank, the plurality of baffle walls defining one or more flow paths for a liquid coolant in the manifold tank, wherein the one or more pedestals are further configured to transfer heat from the one or more components of the PCB to the liquid coolant.

2. The cold tray assembly of claim 1, wherein the cold tray assembly is integrated into a base of a chassis housing the PCB.

3. The cold tray assembly of claim 1, wherein the manifold tank comprises:
an inlet configured to receive the liquid coolant into the manifold tank; and
an outlet configured to eject the liquid coolant from the manifold tank.

4. The cold tray assembly of claim 1, wherein a pedestal of the one or more pedestals comprises a thermally conductive core and a compressible thermal interface material (TIM) gap pad on an external surface of the pedestal.

5. The cold tray assembly of claim 1, wherein a pedestal of the one or more pedestals corresponds to a solid pedestal.

6. The cold tray assembly of claim 1, wherein a pedestal of the one or more pedestals corresponds to a hollow pedestal that comprises a set of internal fins.

7. The cold tray assembly of claim 6, wherein the set of internal fins protrude into the one or more flow paths defined by the plurality of baffle walls, and wherein the set of internal fins align with a direction of flow of the liquid coolant through the one or more flow paths.

8. The cold tray assembly of claim 6, wherein the set of internal fins terminate at a surface of the manifold tank, and wherein the set of internal fins align orthogonally with a direction of flow of the liquid coolant through the one or more flow paths defined by the plurality of baffle walls.

9. The cold tray assembly of claim 1, wherein the manifold tank comprises:
a set of first ports to eject the liquid coolant from the manifold tank to one or more cold plates that are thermally coupled to at least one component of the one or more components mounted on the PCB; and
a set of second ports to receive the liquid coolant from the one or more cold plates into the manifold tank.

10. A dual cold tray device, comprising:
a printed circuit board (PCB);
a first cold tray assembly on a first side of the PCB, wherein the first cold tray assembly comprises a first manifold tank configured to thermally couple with one or more first components on the first side of the PCB;
a second cold tray assembly on a second side of the PCB, the first side being opposite to the second side, wherein the second cold tray assembly comprises a second manifold tank configured to thermally couple with one or more second components on the second side of the PCB; and
one or more support columns that extend between the first manifold tank and the second manifold tank, wherein
the one or more support columns are configured to transfer a liquid coolant between the first manifold tank and the second manifold tank, and the first manifold tank and the second manifold tank are configured to transfer
heat from the one or more first components and the one or more second components to the liquid coolant, respectively.

11. The dual cold tray device of claim 10, wherein a support column of the one or more support columns comprises a hollow support column, and wherein the first manifold tank is fluidically connected to the second manifold tank via the hollow support column.

12. The dual cold tray device of claim 10, wherein the first manifold tank is fluidically connected to the second manifold tank in one of a parallel configuration or a series configuration.

13. The dual cold tray device of claim 10, wherein the first cold tray assembly further comprises a first fin array integrated within the first manifold tank, the first fin array configured to thermally couple with the one or more first components mounted on the first side of the PCB.

14. The dual cold tray device of claim 10, wherein the PCB comprises:
a cold plate configured to thermally couple with a component of the one or more components mounted on the first side of the PCB; and
a plurality of walls that surround the cold plate.

15. The dual cold tray device of claim 14, wherein:
the first cold tray assembly further comprises a slot within a surface of the first manifold tank that faces the first side of the PCB,
the plurality of walls protrudes into the first manifold tank of the first cold tray assembly through the slot, and
the slot is configured to transfer the liquid coolant between the first manifold tank and the cold plate to dissipate heat from the component to the liquid coolant.

16. The dual cold tray device of claim 14, wherein the cold plate comprises a sealing component, and wherein the cold plate is secured to the first manifold tank via the sealing component.

17. The dual cold tray device of claim 10, wherein the second cold tray assembly further comprises a second fin array integrated within the second manifold tank, the second fin array configured to thermally couple with the one or more second components mounted on the second side of the PCB.

18. The dual cold tray device of claim 10, wherein the second cold tray assembly further comprises:
one or more pedestals that extend outward from the second manifold tank, the one or more pedestals configured to thermally couple with the one or more second components on the second side of the PCB; and
a plurality of baffle walls within the second manifold tank, the plurality of baffle walls defining one or more flow paths for the liquid coolant in the second manifold tank, wherein the one or more pedestals are further configured to transfer heat from the one or more second components of the PCB to the liquid coolant.

19. A cold tray assembly mounted to a printed circuit board (PCB), comprising:
a manifold tank;
a plurality of baffle walls within the manifold tank, the plurality of baffle walls defining one or more flow paths for a liquid coolant in the manifold tank; and
one or more slots within a surface of the manifold tank, the one or more slots corresponding to at least one cold plate thermally coupled to one or more components of the PCB, wherein the one or more slots are configured to transfer the liquid coolant between the manifold tank and the at least one cold plate to dissipate heat from the one or more components to the liquid coolant.

20. The cold tray assembly of claim 19, wherein the cold tray assembly is integrated into a lid of a chassis housing the PCB.
